(19) United States
(12) Patent Application Publication
(10) Pub. No.: US 2015/0060979 A1
(43) Pub. Date: Mar. 5, 2015

(54) VERTICAL MEMORY DEVICES AND METHODS OF MANUFACTURING THE SAME

(71) Applicants: Gil-Sung Lee, Seoul (KR); Chang-Seok Kang, Seongnam-si (KR); Ju-Hyung Kim, Yongin-si (KR)

(72) Inventors: Gil-Sung Lee, Seoul (KR); Chang-Seok Kang, Seongnam-si (KR); Ju-Hyung Kim, Yongin-si (KR)

(21) Appl. No.: 14/471,619

(22) Filed: Aug. 28, 2014

(30) Foreign Application Priority Data
Sep. 2, 2013 (KR) 10-2013-0104726

(51) Int. Cl. H01L 27/115; H01L 29/10; H01L 29/423

(52) U.S. Cl. CPC H01L 27/11582; H01L 27/11556; H01L 29/42356; H01L 29/105
USPC 257/314

(57) ABSTRACT

A vertical memory device includes a channel and gate electrodes. The channel extends in a vertical direction with respect to a top surface of a substrate. The gate electrodes are disposed on an outer sidewall of the channel. The gate electrodes includes a ground selection line (GSL), a word line, a string selection line (SSL) and a first dummy word line sequentially stacked from the top surface of the substrate in the vertical direction to be spaced apart from each other. The channel includes an impurity region at a portion adjacent to the SSL.

### CROSS-REFERENCE TO RELATED APPLICATION

This application claims priority under 35 USC §119 to Korean Patent Application No. 10-2013-0104726, filed on Sep. 2, 2013 in the Korean Intellectual Property Office (KIPO), the contents of which are incorporated by reference herein in their entirety.

### FIELD

Example embodiments relate to vertical memory devices and methods of manufacturing the same. More particularly, example embodiments relate to non-volatile memory devices including vertical channels and methods of manufacturing the same.

### BACKGROUND

Recently, a vertical memory device including memory cells and insulation layers stacked alternately and vertically with respect to a surface of a substrate has been developed in order to realize a high degree of integration. In the vertical memory device, a channel protruding vertically from the surface of the substrate may be provided, and the memory cells and the insulation layers surrounding the channel may be stacked. Further, ions or impurities may be implanted into the channel to control electrical characteristics of the vertical memory device.

The electrical characteristics of the vertical memory device may be changed according to a distribution of the ions or impurities.

### SUMMARY

Example embodiments provide a vertical memory device having improved electrical characteristics.

Example embodiments provide a method of manufacturing a vertical memory device having improved electrical characteristics.

According to example embodiments, there is provided a vertical memory device. The vertical memory device includes a channel and gate electrodes. The channel extends in a vertical direction with respect to a top surface of a substrate. The gate electrodes are disposed on an outer sidewall of the channel. The gate electrodes include a ground selection line (GSL), a word line, a string selection line (SSL) and a first dummy word line sequentially stacked from the top surface of the substrate in the vertical direction to be spaced apart from each other.

In example embodiments, the channel may include an impurity region at a portion adjacent to the SSL.

In example embodiments, the gate electrodes may further include a second dummy word line between the word line and the SSL.

In example embodiments, the SSL, the second dummy word line and the word line may be arranged in the vertical direction by the same distance.

In example embodiments, the vertical memory device may further include a dielectric layer structure between the channel and the gate electrodes. The dielectric layer structure may extend from the top surface of the substrate in the vertical direction.

In example embodiments, a top surface of the dielectric layer structure may be located between a bottom surface of the SSL and a top surface of the word line.

In example embodiments, the dielectric layer structure may include a tunnel insulation layer pattern, a charge storage layer pattern and a blocking layer pattern sequentially stacked from the outer sidewall of the channel.

In example embodiments, a single gate insulation layer may be disposed on a portion of the outer sidewall of the channel which is not covered by the dielectric layer structure.

In example embodiments, the vertical memory device may further include a second dummy word line between the word line and the SSL. A top surface of the dielectric layer structure may be located between a bottom surface of the second dummy word line and a top surface of the word line.

In example embodiments, the channel may include a semiconductor pattern disposed on the top surface of the substrate. A top surface of the semiconductor pattern may be located between a top surface of the GSL and a bottom surface of the word line.

In example embodiments, the dielectric layer structure may extend from the top surface of the semiconductor substrate.

In example embodiments, a predetermined turn-on voltage may be applied to the first dummy word line.

In example embodiments, the predetermined turn-on voltage may have a value between a threshold voltage of the SSL and a read voltage of the word line.

According to example embodiments, there is provided a method of manufacturing a vertical memory device. In the method, insulating interlayers and sacrificial layers are formed alternately and repeatedly on a substrate. An opening is formed through the insulating interlayers and the sacrificial layers to expose a top surface of the substrate. A dielectric layer structure is formed on a sidewall of the opening. A channel is formed on the dielectric layer structure and the top surface of the substrate. The sacrificial layers are removed. A GSL, a word line, an SSL and a first dummy word line are sequentially formed at spaces from which the sacrificial layers are removed. An impurity region is formed at a portion of the channel adjacent to the SSL.

In example embodiments, an upper portion of the dielectric layer structure may be removed such that a top surface of the dielectric layer structure may be located between a bottom surface of the SSL and a top surface of the word line.

In example embodiments, a vertical memory device includes a plurality of gate electrodes and insulating layers alternately stacked in a vertical direction from a top surface of a substrate. The method also includes a channel extending from the top surface of the substrate in a vertical direction through the gate electrodes and insulating layers, wherein an upper sidewall region of the channel laterally adjacent to an upper one of the gate electrodes has a different impurity concentration than a lower sidewall region of the channel laterally adjacent to a lower one of the gate electrodes below the upper one of the gate electrodes.

In example embodiments, an upper boundary of the lower sidewall region is laterally adjacent to one of the insulating layers between the upper one of the gate electrodes and the lower one of the gate electrodes.

In example embodiments, the upper one of the gate electrodes is configured to receive a predetermined turn-on voltage having a value different than a value of a threshold voltage of the lower one of the gate electrodes.

In example embodiments, the upper one of the gate electrodes is a dummy word line and the lower one of the gate electrodes is a string selection line (SSL). The plurality of gate electrodes may further include a word line below the SSL and a ground select line (GSL) below the word line. The plurality of gate electrodes may also include a second dummy word line between the SSL and the word line.

In example embodiments, the second dummy word line is configured to receive the predetermined turn-on voltage.

In example embodiments, a lower boundary of the lower sidewall region is laterally adjacent to an insulating layer between the SSL and the second dummy word line.

In example embodiments, the lower sidewall region of the channel has a greater impurity concentration than the upper sidewall region of the channel.

### BRIEF DESCRIPTION OF THE DRAWINGS

Example embodiments will be more clearly understood from the following detailed description taken in conjunction with the accompanying drawings. FIGS. 1A to 31 represent non-limiting, example embodiments as described herein.

FIGS. 1A and 1B are a perspective view and a cross-sectional view, respectively, illustrating a vertical memory device in accordance with example embodiments;

FIGS. 2 to 15 are cross-sectional views illustrating a method of manufacturing the vertical memory device of FIGS. 1A and 1B;

FIG. 16 is a cross-sectional view illustrating a vertical memory device in accordance with example embodiments;

FIG. 17 is a cross-sectional view illustrating a method of manufacturing the vertical memory device of FIG. 16;

FIG. 18 is a cross-sectional view illustrating a vertical memory device in accordance with example embodiments;

FIGS. 19 to 23 are cross-sectional views illustrating a method of manufacturing the vertical memory device of FIG. 18;

FIG. 24 is a cross-sectional view illustrating a vertical memory device in accordance with example embodiments;

FIGS. 25 to 30 are cross-sectional views illustrating a method of manufacturing the vertical memory device of FIG. 24; and

FIG. 31 is a block diagram illustrating a schematic construction of an information processing system in accordance with example embodiments.

### DETAILED DESCRIPTION

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this description will be thorough and complete, and will fully convey the scope of the present inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, fourth etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

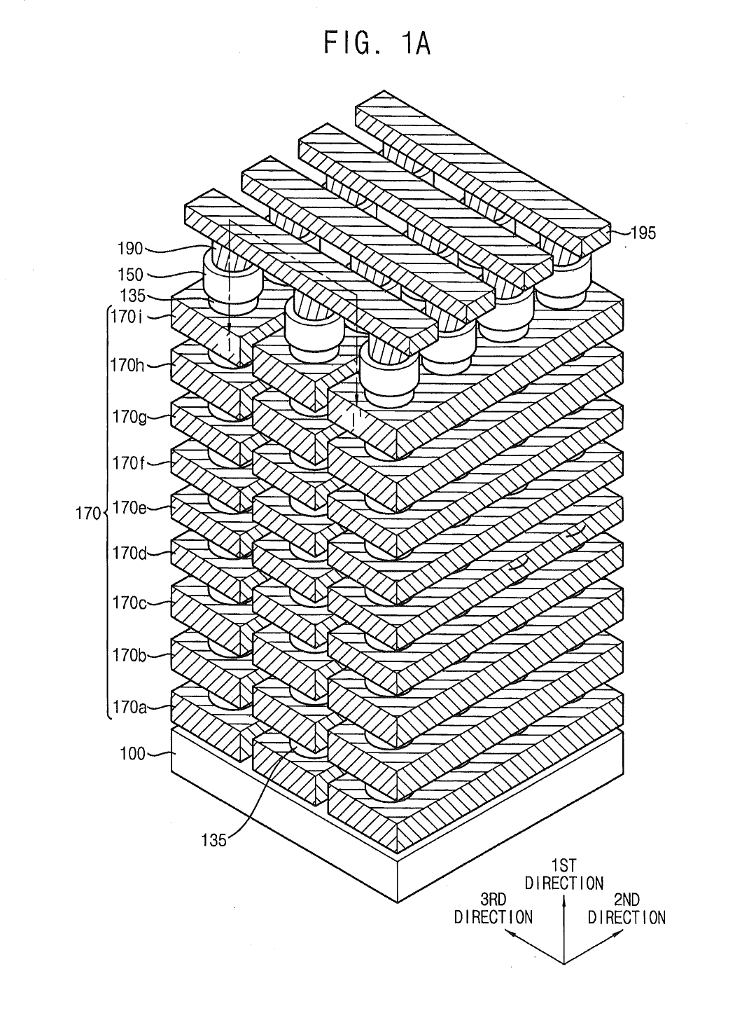

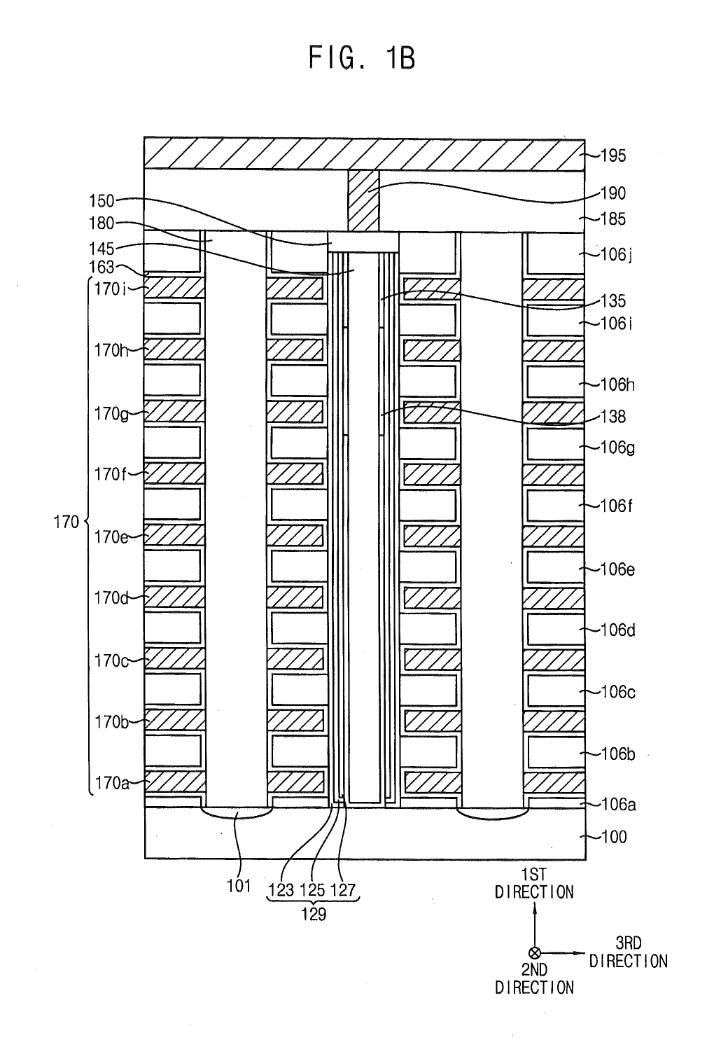

FIGS. 1A and 1B are a perspective view and a cross-sectional view, respectively, illustrating a vertical memory device in accordance with example embodiments. Specifically, FIG. 1B is a cross-sectional view taken along a line I-I′ of FIG. 1A.

For the convenience of explanation, FIG. 1A does not show all elements of the vertical semiconductor device, but only shows some elements thereof, e.g., a substrate, a channel, a gate electrode, a pad, a bit line contact and a bit line. In all figures in this specification, a direction substantially perpendicular to a top surface of the substrate is referred to as a first direction, and two directions substantially parallel to the top surface of the substrate and substantially perpendicular to each other are referred to as a second direction and a third direction. Additionally, a direction indicated by an arrow in the figures and a reverse direction thereto are considered as the same direction.

Referring to FIGS. 1A and 1B, the vertical memory device may include a channel 135 protruding vertically from a substrate 100, a dielectric layer structure 129 surrounding an outer sidewall of the channel 135 and gate electrodes 170 stacked on the dielectric layer structure 129 along the first direction to partially surround the channel 135. A pad 150 may be disposed on the channel 135. The vertical memory device may further include a bit line contact 190 in contact with the pad 150, and a bit line 195 electrically connected to the bit line contact 190. A first impurity region 101 may be formed at an upper portion of the substrate 100 between the adjacent channels 135, and a second impurity region 138 may be formed at a predetermined region of an upper portion of the channel 135.

The substrate 100 may include a semiconductor material, e.g., silicon, germanium, etc.

The channel 135 may have a substantially hollow cylindrical shape or a substantially cup shape. A plurality of the channels 135 may be arranged along the second direction to form a channel column. A plurality of the channel columns may be arranged along the third direction. The channel may include polysilicon or single crystalline silicon.

A first filling layer pattern 145 having a substantially pillar shape or a substantially solid cylindrical shape may be formed in the channel 135. The first filling layer pattern 145 may include an insulation material such as silicon oxide.

The dielectric layer structure 129 may include a plurality of layers stacked in the third direction from the outer sidewall of the channel 135. In example embodiments, the dielectric layer structure 129 may include a tunnel insulation layer pattern 127, a charge storage layer pattern 125 and a first blocking layer pattern 123. In one example embodiment, the first blocking layer pattern 123 may be omitted.

In example embodiments, the first blocking layer pattern 123 may include an oxide such as silicon oxide, the charge storage layer pattern 125 may include a nitride such as silicon nitride or a metal oxide, and the tunnel insulation layer pattern 127 may include an oxide such as silicon oxide.

The pad 150 may be formed on the first filling layer pattern 145, the channel 135 and the dielectric layer structure 129 to be electrically connected to the bit line 195 via the bit line contact 190. The pad 150 may serve as a source/drain region through which charges are moved or transferred to the channel 135. The pad 150 may include polysilicon or single crystalline silicon. The pad 150 may further include, e.g., n-type impurities such as phosphorus (P) or arsenic (As).

The gate electrodes 170 may be disposed on the dielectric layer structure 129 to be spaced apart from each other in the first direction. In example embodiments, each gate electrode 170 may surround the channel 135 and may extend in the second direction.

The gate electrode 170 may include a metal having a low electrical resistance or a nitride thereof. For example, the gate electrode 170 may include tungsten (W), tungsten nitride, titanium (Ti), titanium nitride, tantalum (Ta), tantalum nitride, platinum (Pt), etc. In one example embodiment, the gate electrode 170 may have a multi-layered structure including a barrier layer that may include the metal nitride and a metal layer.

Lowermost gate electrodes 170a and 170b at 2 levels may serve as ground selection lines (GSLs), gate electrodes 170c, 170d, 170e and 170f at 4 levels on the GSLs may serve as word lines, and gate electrodes 170g and 170h at 2 levels on the word lines may serve as string selection lines (SSLs).

In example embodiments, a dummy word line may be disposed on the SSL. An uppermost gate electrode 170i may serve as the dummy word line.

As described above, the GSL, the word line and the SSL may be formed at 2 levels, 4 levels and 2 levels, respectively. However, the number of the levels at which the GSL, the word line and the SSL are formed is not specifically limited. In some example embodiments, the GSL and the SSL may be formed at a single level, respectively, and the word line may be formed at 2, 8 or 16 levels.

Distances between the adjacent gate electrodes 170 in one string may be the same as each other. In one example embodiment, a distance between the SSL 170g and the word line 170f may be greater than distances between the adjacent word lines 170c, 170d, 170e and 170f.

Insulating interlayer patterns 106 (106a-106j) may be disposed between the adjacent gate electrodes 170 in the first direction. The insulating interlayer patterns 106 may include a silicon oxide based material, e.g., silicon dioxide (SiO₂), silicon carbooxide (SiOC) or silicon fluorooxide (SiOF). The gate electrodes 170 included in one string may be insulated from each other by the insulating interlayer patterns 106.

In one example embodiment, a second blocking layer 163 may be formed along surfaces of the insulating interlayer patterns 106 and an outer sidewall of the dielectric layer structure 129. The second blocking layer 163 may include silicon oxide or a metal oxide. For example, the metal oxide may include aluminum oxide, hafnium oxide, lanthanum oxide, lanthanum aluminum oxide, lanthanum hafnium oxide, hafnium aluminum oxide, titanium oxide, tantalum oxide, zirconium oxide, etc. The second blocking layer 163 may have a multi-layered structure including, e.g., a silicon oxide layer and a metal oxide layer.

The first impurity region 101 may be formed at the upper portion of the substrate 100 between the adjacent channel columns. The first impurity region 101 may extend in the second direction and serve as a common source line (CSL). The first impurity region 101 may include n-type impurities such as phosphorus or arsenic. In one example embodiment, a metal silicide pattern (not illustrated) such as a cobalt silicide pattern may be further formed on the first impurity region 101.

A second filling layer pattern 180 may be disposed on the first impurity region 101 to fill a space between the adjacent strings. The second filling layer pattern 180 may include an insulation material, e.g., silicon oxide. The adjacent strings may be insulated from each other by the second filling layer pattern 180.

A second impurity region 138 may be formed at an upper portion of the channel 135 adjacent to the SSL. In example embodiments, the second impurity region 138 may be formed at a portion of the channel 135 adjacent to the gate electrodes 170g and 170h serving as the SSL. The second impurity region 138 may include p-type impurities such as boron (B), indium (In) or gallium (Ga).

As illustrated in FIG. 1B, the second impurity region 138 may have a length sufficiently covering the SSLs 170g and 170h. In this case, a threshold voltage (Vth) of the SSLs may be controlled by the second impurity region 138.

Specifically, during an operation of the vertical memory device, a selection and a non-selection of a particular string may be determined according to a combination of voltages applied to the bit line and the SSL. A distribution of the Vth of the SSL may be controlled within a range between the voltage for the selection and the voltage for the non-selection. Thus, the second impurity region 138 may be formed at the portion of the channel 135 adjacent to the SSL for controlling the distribution of the Vth.

However, as the degree of integration of the vertical memory device becomes higher, a voltage applied to each memory cell may be decreased to reduce power consumption. Accordingly, the distribution of the Vth may not be controlled solely by the formation of the second impurity region 138.

Additionally, during the formation of the second impurity region 138, impurities may be diffused to undesired regions, e.g., a portion of the channel 135 adjacent to an uppermost word line 170f and/or a portion of the channel 135 adjacent to the pad 150. Thus, the second impurity region 138 may be excessively extended to result in an over-tail phenomenon. In this case, resistances between the SSL and the pad 150 and/or between the SSL and the word line may be increased so that a cell current may be decreased.

In example embodiments, the dummy word line 170i may be further disposed on the SSL 170h. The dummy word line 170i may control the distribution of the Vth of the SSL within a substantially constant level and may prevent the reduction of the cell current.

For example, the dummy word line 170i may be maintained at a turn-on state by a predetermined buffer voltage. In example embodiments, the buffer voltage between the Vth of the SSL and a read voltage (Vread) of the word line may be applied to the dummy word line 170i. For example, in the case that the Vth of the SSL is about 2V and the Vread of the word line is about 20V, the buffer voltage ranging from about 7V to about 10V may be applied to the dummy word line 170i.

The resistance between the SSL and the pad 150 may be decreased by the buffer voltage so that the distribution of the Vth of the SSL may be reduced and the reduction of the cell current may be prevented. A portion of the channel 135 adjacent to the dummy word line 170i may substantially serve as a lightly doped drain (LDD) which may be formed by implanting n-type impurities in order to achieving the sufficient cell current.

An upper insulation layer 185 may be formed on an uppermost insulating interlayer pattern 106j, the pad 150 and the second filling layer pattern 180. The bit line contact 190 may be formed through the upper insulation layer 185 to contact the pad 150. The bit line 195 may be disposed on the upper insulation layer 185 to be electrically connected to the bit line contact 190. In example embodiments, a plurality of the bit line contacts 190 may form an array comparable to an arrangement of the pad 150 or the channel 135. The bit line 195 may extend in the third direction and a plurality of the bit lines 195 may be arranged along the second direction.

The upper insulation layer 185 may include an insulation material, e.g., silicon oxide. The bit line contact 190 and the bit line 195 may include a conductive material, e.g., a metal, a metal nitride or doped polysilicon.

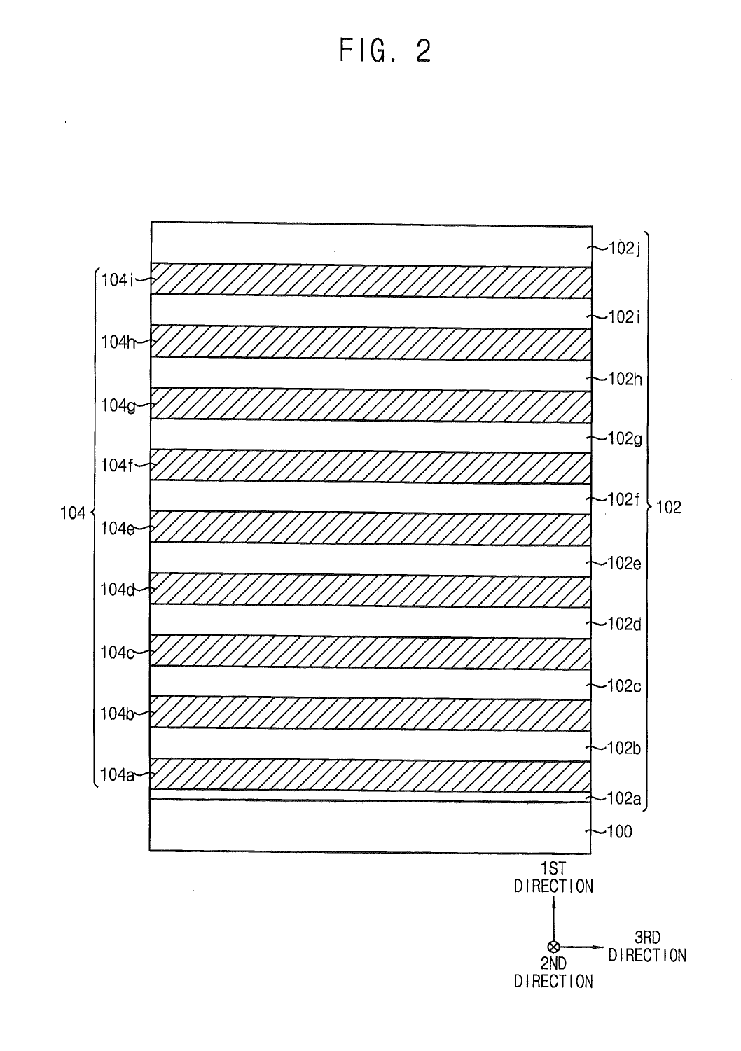

FIGS. 2 to 15 are cross-sectional views illustrating a method of manufacturing the vertical memory device of FIGS. 1A and 1B.

Referring to FIG. 2, an insulating interlayer 102 and a sacrificial layer 104 may be alternately and repeatedly formed on a substrate 100. A plurality of the insulating interlayers 102 (102a-102j) and a plurality of the sacrificial layers 104 (104a-104i) may be alternately formed on each other at a plurality of levels.

The substrate 100 may include a semiconductor material, e.g., single crystalline silicon and/or germanium.

In example embodiments, the insulating interlayer 102 may be formed using a silicon oxide based material, e.g., silicon dioxide, silicon carbooxide or silicon fluorooxide. The sacrificial layer 104 may be formed using a material that may have an etching selectivity with respect to the insulating interlayer 102 and may be easily removed by a wet etching process. For example, the sacrificial layer 104 may be formed using a silicon nitride or silicon boronitride (SiBN).

The insulating interlayer 102 and the sacrificial layer 104 may be formed by a chemical vapor deposition (CVD) process, a plasma enhanced chemical vapor deposition (PECVD) process, an atomic layer deposition (ALD) process, etc. A lowermost insulating interlayer 102a may be formed by performing a thermal oxidation process on the substrate 100.

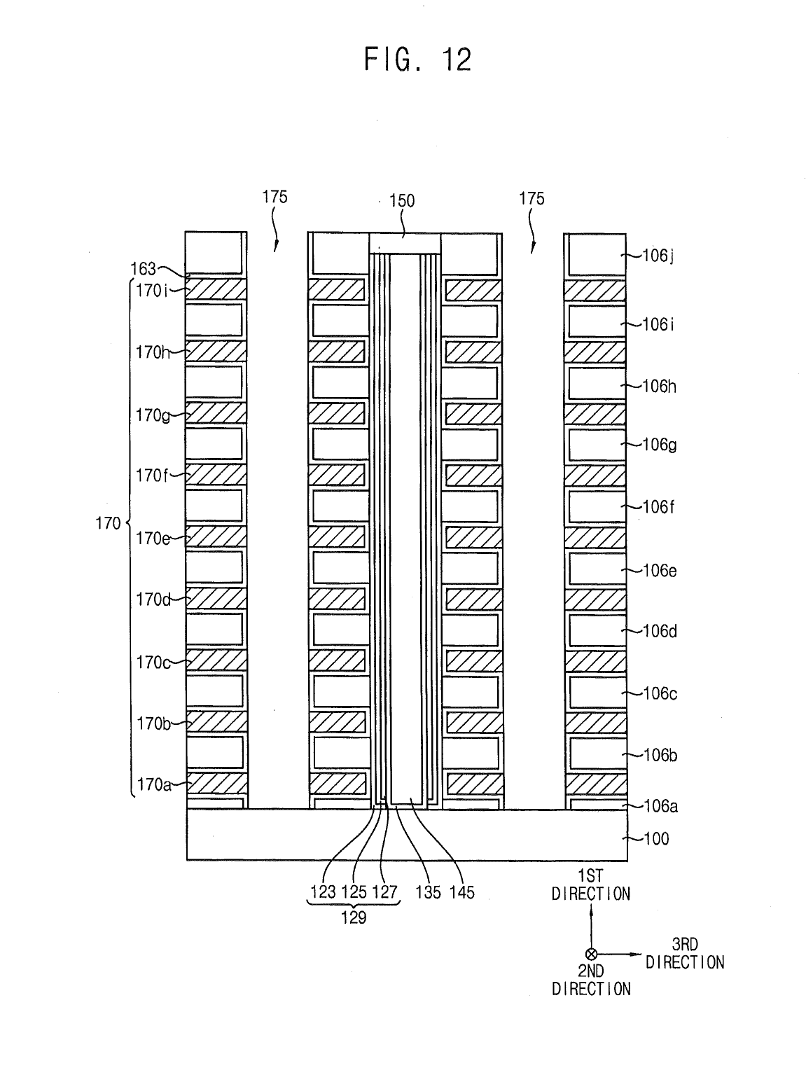

The sacrificial layers 104 may be removed in a subsequent process to provide spaces for a GSL, a word line, an SSL and a dummy word line (refer to FIG. 12). Thus, the number of the insulating interlayers 102 and the sacrificial layers 104 may be adjusted in consideration of the number of the GSLs, the word lines, the SSLs and the dummy word lines. In example embodiments, each of the GSL and the SSL may be formed at 2 levels, and the word line may be formed at 4 levels. The dummy word line may be formed at a single level on the SSL. Accordingly, the sacrificial layers 104 may be formed at 9 levels, and the insulating interlayers 102 may be formed at 10 levels. In one example embodiment, each of the GSL and the SSL may be formed at a single level, and the word line may be formed at 2, 8 or 16 levels. In this case, the sacrificial layers 104 may be formed at 5, 11 or 19 levels, and the insulating interlayers 102 may be formed at 6, 12 or 20 levels. However, the number of the GSL, the SSL and the word lines may not be limited herein.

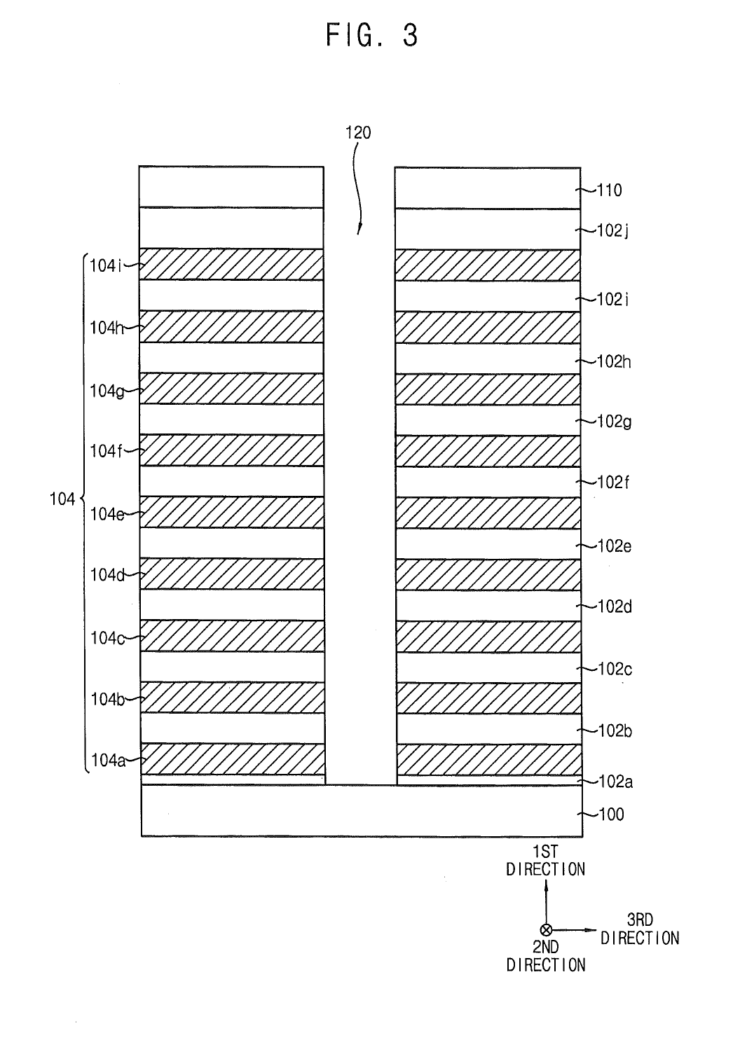

Referring to FIG. 3, a first opening 120 may be formed through the insulating interlayers 102 and the sacrificial layers 104.

In example embodiments, a hard mask 110 may be formed on an uppermost insulating interlayer 102j. The insulating interlayers 102 and the sacrificial layers 104 may be partially etched by, e.g., a dry etching process using the hard mask 110 as an etching mask to form the first opening 120. A top surface of the substrate 100 may be partially exposed by the first opening 120. The first opening 120 may extend in the first direction.

The hard mask 110 may be formed using a material that may have an etching selectivity with respect to the insulating interlayers 102 and the sacrificial layers 104. For example, the hard mask 110 may be formed using polysilicon or amorphous silicon.

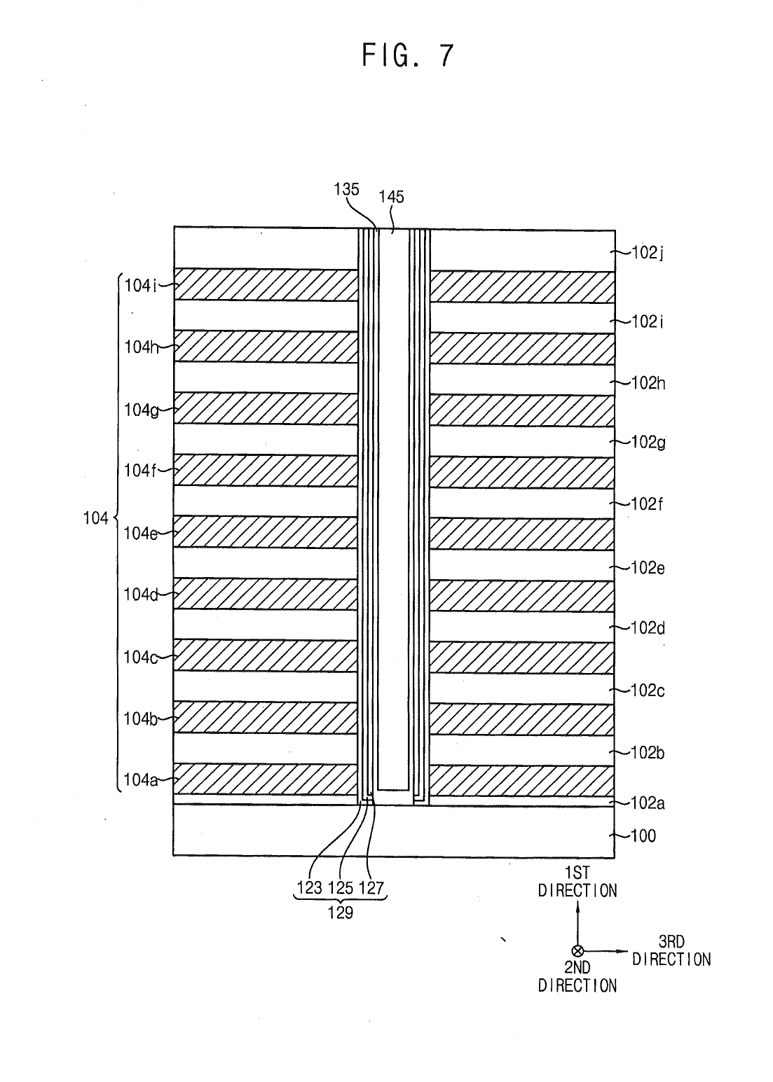

A channel 135 (refer to FIG. 7) may be formed in the first opening 120. Thus, a plurality of the channels 135 may be arranged in the second and third directions.

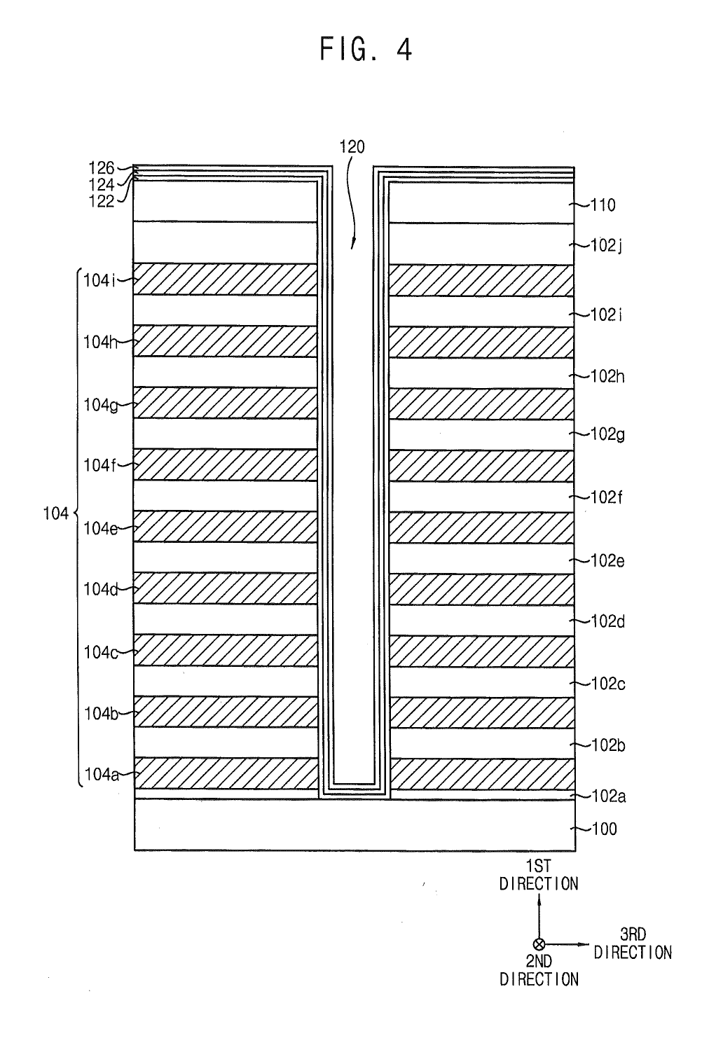

Referring to FIG. 4, a first blocking layer 122, a charge storage layer 124 and a tunnel insulation layer 126 may be sequentially formed on an inner wall of the first opening 120 and a top surface of the hard mask 110.

In example embodiments, the first blocking layer 122 may be formed using an oxide, e.g., silicon oxide, the charge storage layer 124 may be formed using silicon nitride or a metal oxide, and the tunnel insulation layer 126 may be formed using an oxide, e.g., silicon oxide. The first blocking layer 122, the charge storage layer 124 and the tunnel insulation layer 126 may be formed by a CVD process, a PECVD process, an ALD process, etc. In one example embodiment, the formation of the first blocking layer 122 may be omitted.

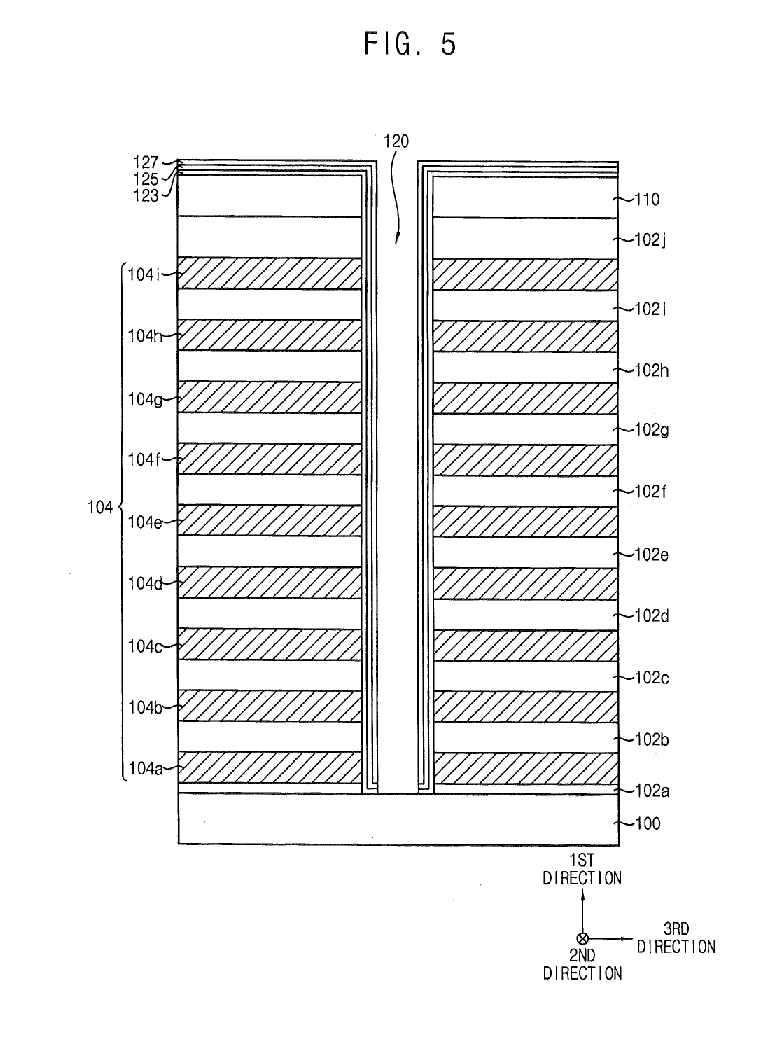

Referring to FIG. 5, the first blocking layer 122, the charge storage layer 124 and the tunnel insulation layer 126 may be anisotropically etched to partially expose the top surface of the substrate 100. Accordingly, a first blocking layer pattern 123, a charge storage layer pattern 125 and a tunnel insulation layer pattern 127 may be formed on a sidewall of the first opening 120 and the top surface of the hard mask 110.

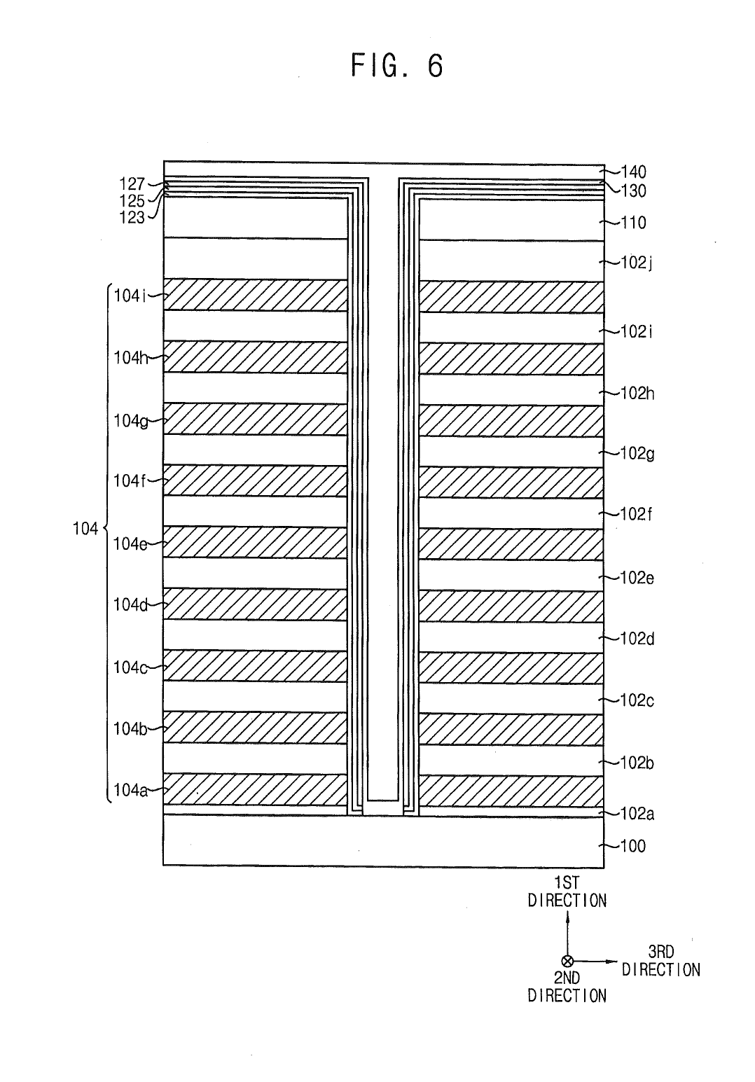

Referring to FIG. 6, a channel layer 130 may be formed on the tunnel insulation layer pattern 127 and the exposed top surface of the substrate 100, and then a first filling layer 140 may be formed on the channel layer 140 to sufficiently fill a remaining portion of the first opening 120. The channel layer 130 may be formed using polysilicon or amorphous silicon. The first filling layer 140 may be formed using an insulation material, e.g., silicon oxide.

In one example embodiment, a heat treatment or a laser beam irradiation may be further performed on the channel layer 130. In this case, the channel layer 130 may include single crystalline silicon and defects in the channel layer 140 may be cured.

Referring to FIG. 7, the first filling layer 140, the channel layer 130, the tunnel insulation layer pattern 127, the charge storage layer pattern 125, the first blocking layer pattern 123 and the hard mask 110 may be planarized until a top surface of the uppermost insulating interlayer 102j is exposed to form a first filling layer pattern 145 and a channel 135 in the first opening 120. The planarization process may include an etch-back process or a chemical mechanical polishing (CMP) process.

Accordingly, a multi-stacked structure including the first blocking layer pattern 123, the charge storage layer pattern 125, the tunnel insulation layer pattern 127, the channel 135 and the first filling layer pattern 145 may be formed in the first opening 120. Hereinafter, a structure including the first blocking layer pattern 123, the charge storage layer pattern 125 and the tunnel insulation layer pattern 127 may be defined as a dielectric layer structure 129.

In example embodiments, the dielectric layer structure 129 may have a substantially hollow cylindrical shape or a substantially straw shape. The channel 135 may have a substantially cup shape. The first filling layer pattern 145 may have a substantially solid cylindrical shape or a substantially pillar shape.

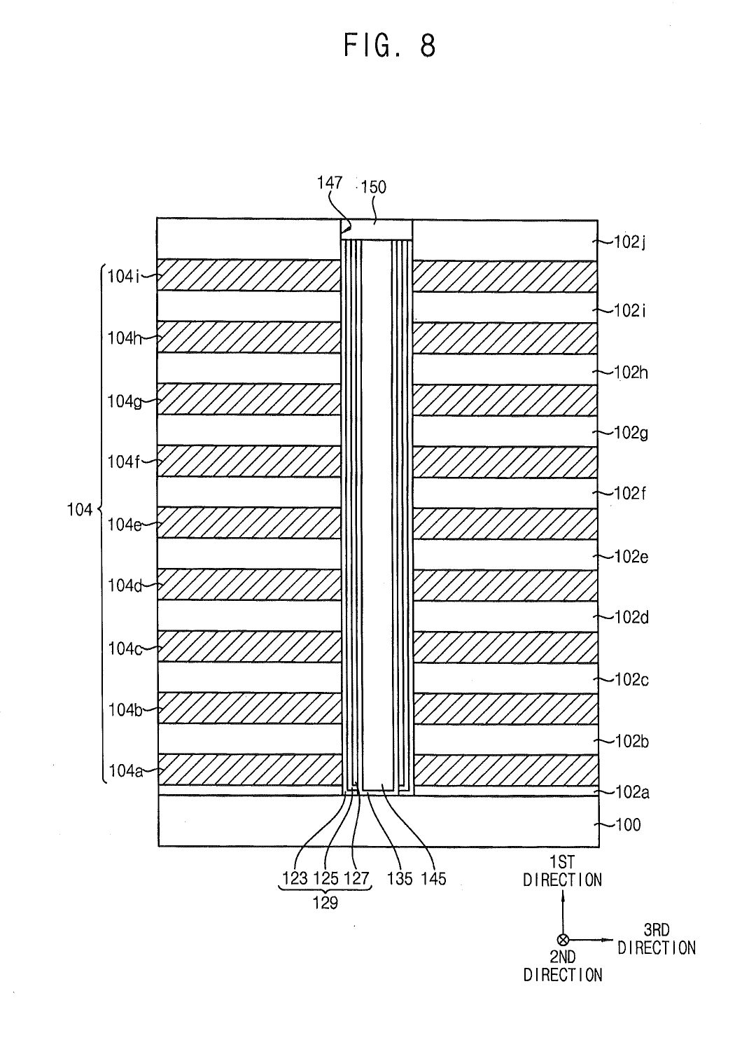

Referring to FIG. 8, upper portions of the dielectric layer structure 129, the channel 135 and the first filling layer pattern 145 may be partially removed to form a recess 147, and then a pad 150 capping the recess 147 may be formed.

In example embodiments, an upper portion of the multi-stacked structure may be removed by an etch-back process to form the recess 147. A pad layer sufficiently filling the recess 147 may be formed on the uppermost insulating interlayer 102j. An upper portion of the pad layer may be planarized until the top surface of the uppermost insulating interlayer 102j is exposed to obtain the pad 150. In example embodiments, the pad layer may be formed using polysilicon or doped polysilicon. In one example embodiment, a preliminary pad layer may be formed using amorphous silicon, and then a crystallization process may be performed thereon to form the pad layer. The planarization process may include a CMP process.

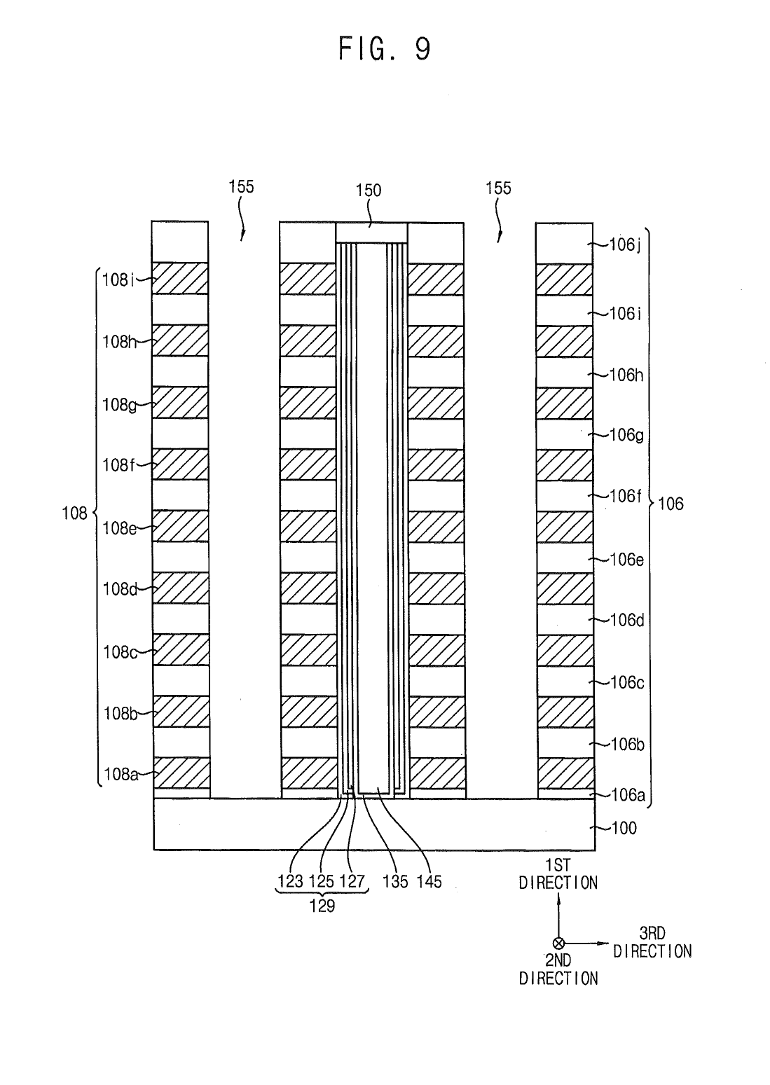

Referring to FIG. 9, a second opening 155 may be formed through the insulating interlayers 102 and the sacrificial layers 104.

In example embodiments, a hard mask (not illustrated) may be formed on the uppermost insulating interlayer 102j, and then the insulating interlayers 102 and the sacrificial layers 104 may be partially etched by, e.g., a dry etching process using the hard mask as an etching mask.

In example embodiments, the top surface of the substrate 100 may be partially exposed by the second opening 155. The second opening 155 may extend in the second direction, and a plurality of the second openings 155 may be formed along the third direction. By the formation of the second opening 155, the insulating interlayers 102 and the sacrificial layers 104 may be transformed into insulating interlayer patterns 106 and the sacrificial layer patterns 108 (108a-108i). Each of the insulating interlayer pattern 106 and the sacrificial layer pattern 108 may extend in the second direction.

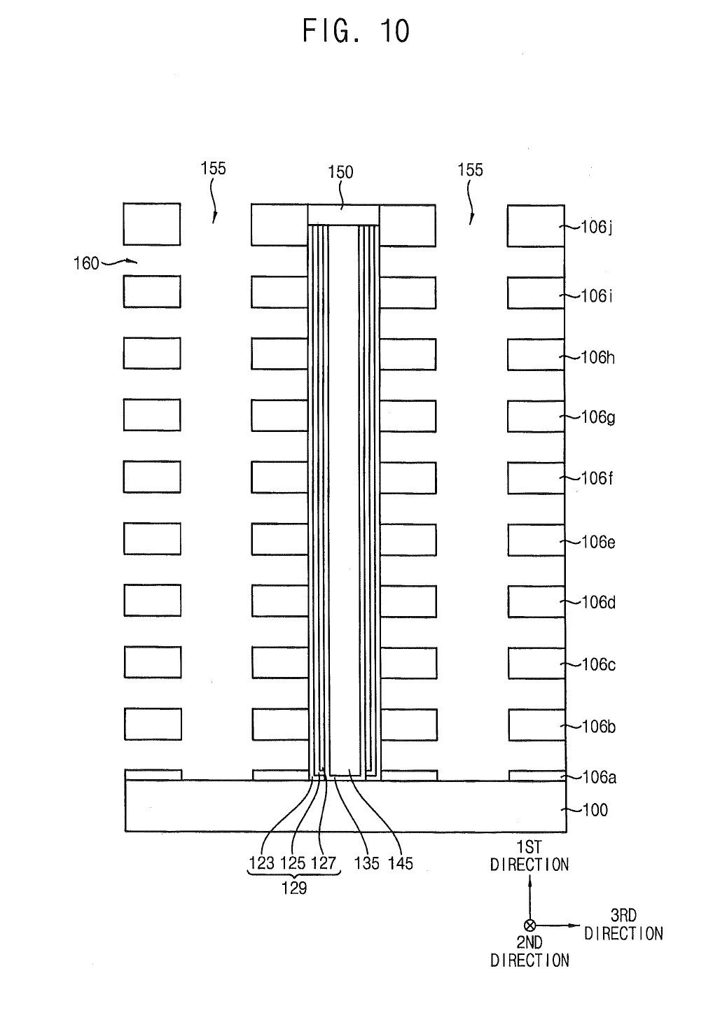

Referring to FIG. 10, the sacrificial layer patterns 108, sidewalls of which are exposed by the second opening 155 may be removed. In example embodiments, the sacrificial layer patterns 108 may be removed by a wet etching process using, e.g., phosphoric acid and/or sulfuric acid as an etching solution.

A gap 160 may be defined by a region at which the sacrificial layer pattern 108 is removed. A plurality of the gaps 160 may be formed along the first direction, and each gap 160 may be formed between the adjacent insulating interlayer patterns 106. An outer sidewall of the dielectric layer structure 129 may be partially exposed by the gap 160.

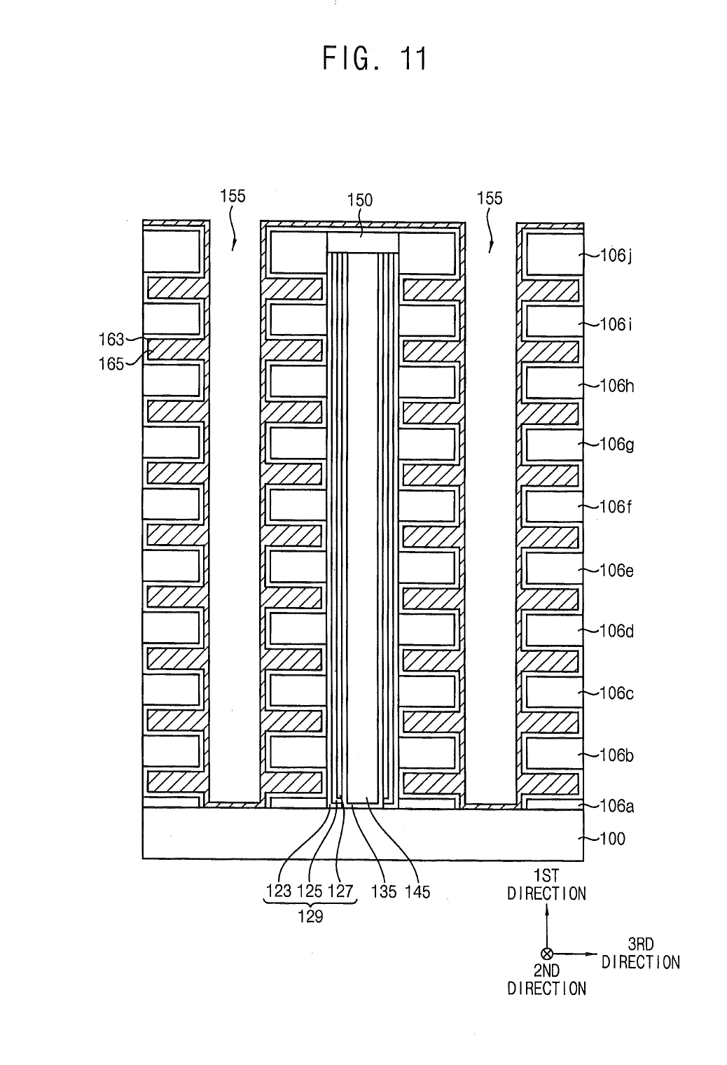

Referring to FIG. 11, a gate electrode layer 165 may be formed on the exposed outer sidewall of the dielectric layer structure 129, surfaces of the insulating interlayer patterns 106, inner walls of the gaps 106, the exposed top surface of the substrate 100 and a top surface of the pad 150. In one example embodiment, a second blocking layer 163 may be further formed prior to forming the gate electrode layer 165.

The gate electrode layer 165 may sufficiently fill the gaps 160 and partially fill the second opening 155.

The second blocking layer 163 may be formed using, e.g., silicon oxide or a metal oxide. The metal oxide may include, e.g., aluminum oxide, hafnium oxide, lanthanum oxide, lanthanum aluminum oxide, lanthanum hafnium oxide, hafnium aluminum oxide, titanium oxide, tantalum oxide or zirconium oxide. The second blocking layer 163 may be formed as a multi-layered structure including, e.g., a silicon oxide layer and a metal oxide layer.

The gate electrode layer 165 may be formed using a metal or a metal nitride. For example, the gate electrode layer 165 may be formed using tungsten, tungsten nitride, titanium, titanium nitride, tantalum, tantalum nitride, platinum, etc. In one example embodiment, the gate electrode layer 165 may be formed as a multi-layered structure including a barrier layer that may include the metal nitride and a metal layer.

The second blocking layer 163 and the gate electrode layer 165 may be formed by a CVD process, a PECVD process, an ALD process, a sputtering process, etc.

Referring to FIG. 12, the gate electrode layer 165 may be partially removed to form a gate electrode 170 in the gap 160 of each level.

For example, an upper portion of the gate electrode layer 165 may be planarized until the uppermost insulating interlayer pattern 106j is exposed. A portion of the second blocking layer 163 which is formed on the uppermost insulating interlayer pattern 106j and the pad 150 may also be removed during the planarization process. A portion of the gate electrode layer 165 formed in the second opening 155 may be etched to obtain the gate electrodes 170. A portion of the second blocking layer 163 which is formed on the top surface of the substrate 100 may also be removed during the etching process so that a third opening 175 exposing the top surface of the substrate 100 may be defined.

In example embodiments, the planarization process may include a CMP process, and the etching process may include a wet etching process.

In one example embodiment, a portion of the second blocking layer 163 which is formed on sidewalls of the insulating interlayer patterns 106 may also be removed during the etching process. In this case, a second blocking layer pattern may be formed on the inner wall of each gap 160.

The gate electrodes 170 may include the GSL, the word line, the SSL and the dummy word line sequentially stacked and spaced apart from one another in the first direction. For example, lowermost gate electrodes 170a and 170b at 2 levels may serve as the GSL. Gate electrodes 170c, 170d, 170e and 170f at 4 levels on the GSL may serve as the word line. Gate electrodes 170g and 170h at two levels may serve as the SSL. A gate electrode 170i on the SSL may serve as the dummy word line.

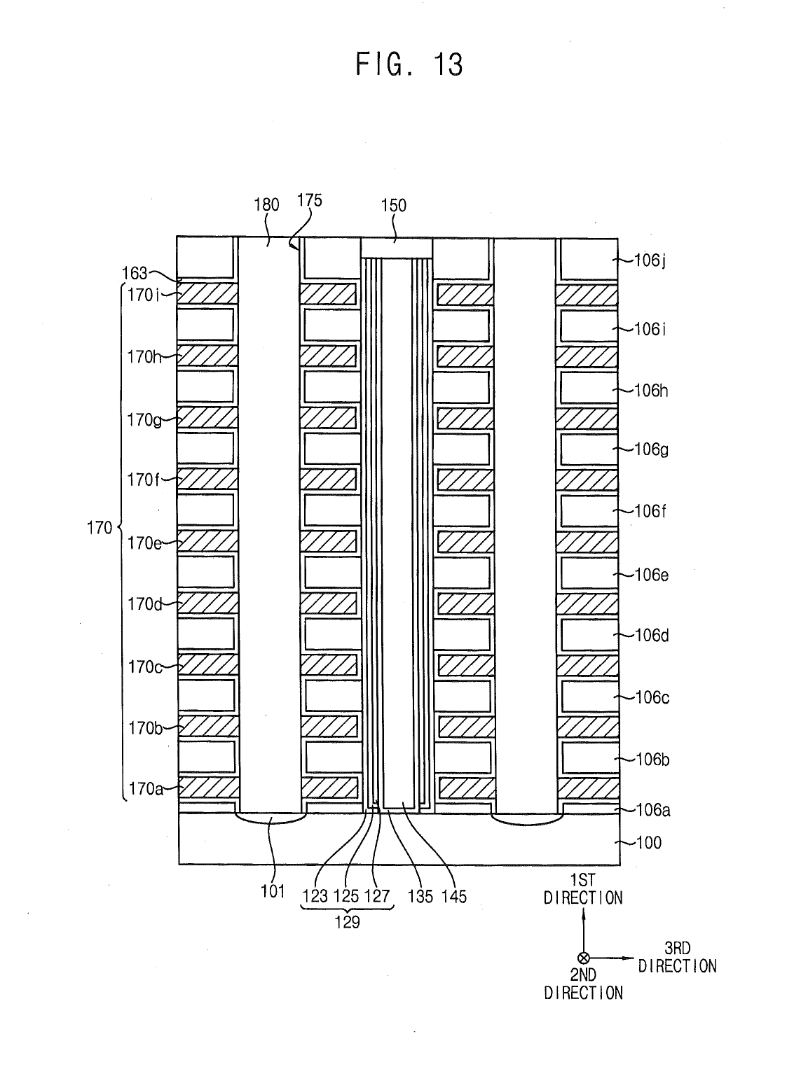

Referring to FIG. 13, a first impurity region 101 may be formed at an upper portion of the substrate 100 exposed by the third opening 175, and then a second filling layer pattern 180 may be formed to fill the third opening 175.

In example embodiments, an ion-implantation mask (not illustrated) covering the pad 150 may be formed on the uppermost insulating interlayer pattern 106j. A first impurity may be implanted through the third opening 175 using the ion-implantation mask to form the first impurity region 101. The first impurity may include n-type impurities such as phosphorus or arsenic. The first impurity region 101 may serve as a CSL extending in the second direction.

A metal silicide pattern (not illustrated) including, e.g., nickel silicide or cobalt silicide may be further formed on the first impurity region 101.

A second filling layer sufficiently filling the third opening 175 may be formed on the substrate 100, the uppermost insulating interlayer pattern 106j and the pad 150. An upper portion of the second filling layer may be planarized by a CMP process or an etch-back process until the uppermost insulating interlayer pattern 106j is exposed to form the second filling layer pattern 180. The second filling layer may be formed using an insulation material, e.g., silicon oxide.

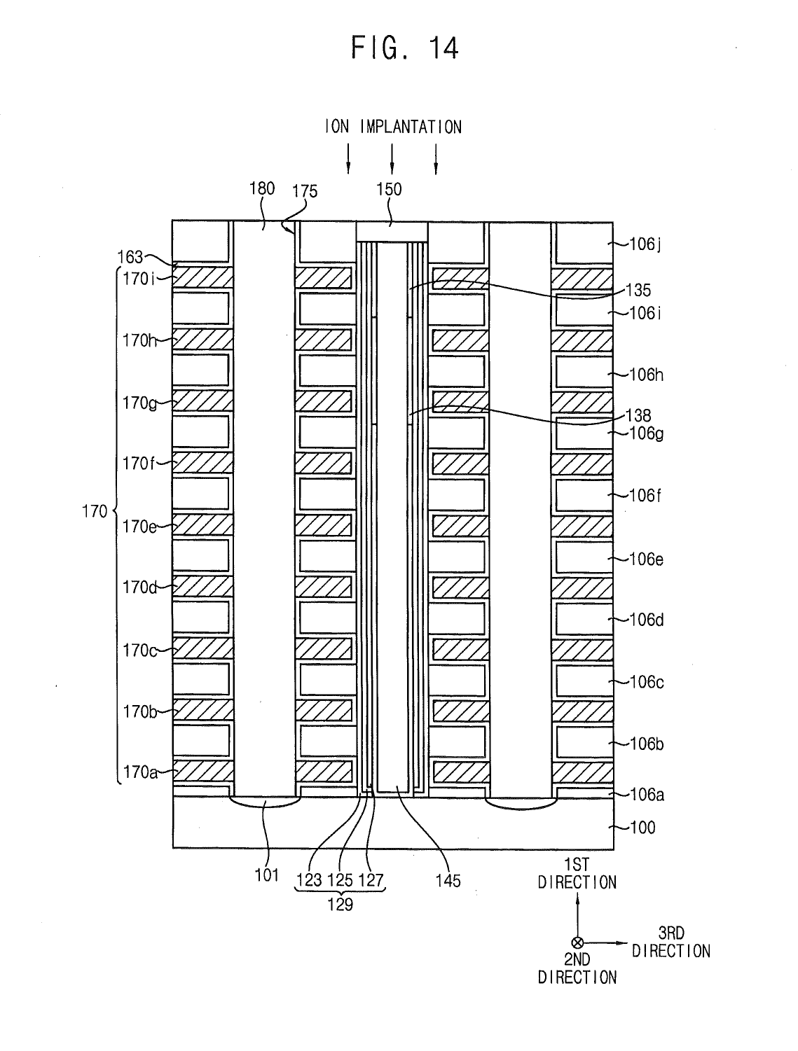

Referring to FIG. 14, a second impurity region 138 may be formed at a portion of the channel 135 adjacent to the gate electrodes 170g and 170h serving as the SSL.

In example embodiments, a second impurity may be implanted by an ion-implantation process through the pad 150 to form the second impurity region 138. The second impurity may include p-type impurities, e.g., boron, indium or gallium. In the ion-implantation process, a projection range (Rp) may be controlled so that the second impurity region 138 may have a length substantially covering a distance between the SSLs 170g and 170h. For example, a top portion of the second impurity region 138 may be higher than a top surface of the gate electrode 170h, and a bottom portion of the second impurity region 138 may be lower than a bottom surface of the gate electrode 170g.

In the case that the second impurity region 138 is diffused to a portion of the channel 135 adjacent to the pad 150 to cause an over-tail phenomenon, a threshold voltage of the SSL may be increased. According to example embodiments, the uppermost gate electrode 170i may serve as the dummy word line to which a predetermined turn-on voltage may be applied, so that the threshold voltage may be suppressed from being increased.

In one example embodiment, a third impurity may be further implanted into the pad 150. The third impurity may include n-type impurities such as phosphorous or arsenic.

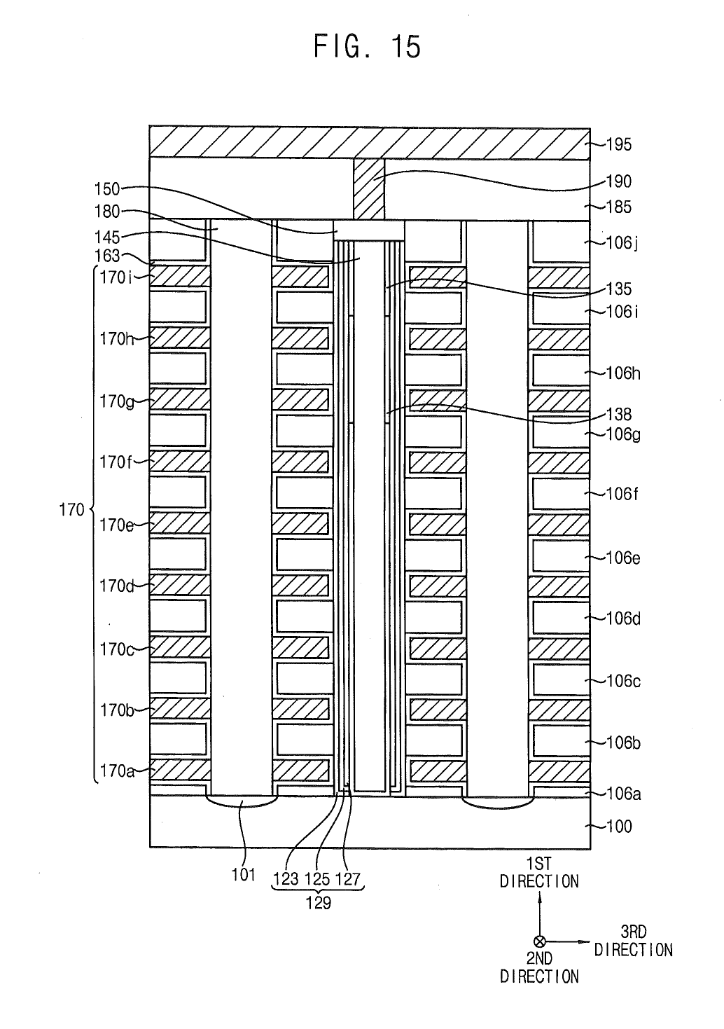

Referring to FIG. 15, an upper insulation layer 185 may be formed on the uppermost insulating interlayer pattern 106j, the second filling layer pattern 180 and the pad 150. The upper insulation layer 185 may be formed using an insulation material such as silicon oxide by, e.g., a CVD process.

A bit line contact 190 may be formed through the upper insulation layer 185 to contact the pad 15Q. The bit line contact 190 may be formed using a metal, a metal nitride or a doped polysilicon.

A bit line 195 may be formed on the upper insulation layer 185 to be electrically connected to the bit line contact 190. The bit line 195 may be formed using a metal, a metal nitride or a doped polysilicon by, e.g., an ALD process or a sputtering process.

In example embodiments, a plurality of the bit line contacts 190 may be formed according to the arrangement of the pads 150 to form a bit line contact array. The bit line 195 may be formed to extend in the third direction, and a plurality of the bit lines 195 may be formed along the second direction.

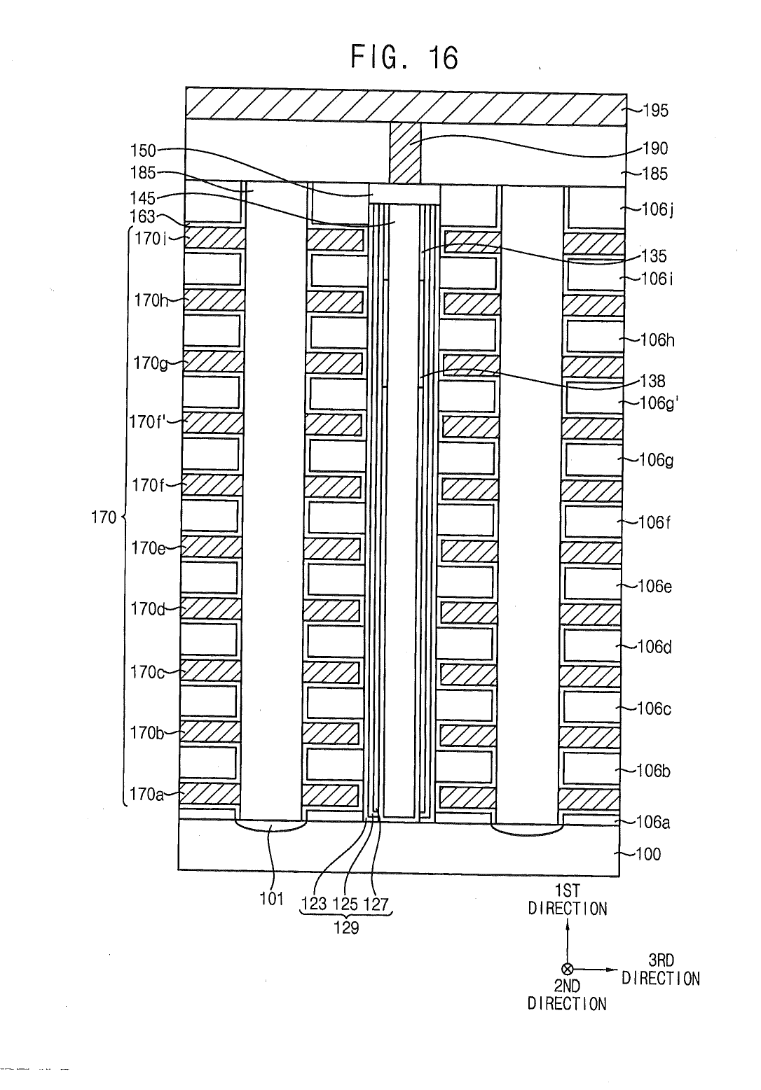

FIG. 16 is a cross-sectional view illustrating a vertical memory device in accordance with example embodiments. The vertical memory device may have a structure and/or a construction substantially the same as or similar to those illustrated with reference to FIGS. 1A and 1B except for an arrangement of gate electrodes. Thus, detailed descriptions on elements substantially the same as or similar to those illustrated with reference to FIGS. 1A and 1B are omitted. Like reference numerals are used to indicate like elements.

Referring to FIG. 16, the vertical memory device may include gate electrodes 170 at one more level than those illustrated in FIG. 1B. For example, the vertical memory device may include the gate electrodes 170 at 10 levels as illustrated in FIG. 16.

In example embodiments, lowermost gate electrodes 170a and 170b at 2 levels may serve as GSLs, and gate electrodes 170c, 170d, 170e and 170f at 4 levels may serve as word lines. A gate electrode 170f′ at 1 level on the word lines may serve as a second dummy word line, and gate electrodes 170g and 170h at 2 levels on the second dummy word line may serve as SSLs. An uppermost gate electrode 170i on the SSLs may serve as a first dummy word line. Thus, the SSLs 170g and 170h may be disposed between the first dummy word line 170i and the second dummy word line 170f′.

As described with reference to FIGS. 1A and 1B, a predetermined buffer voltage may be applied to the dummy word line to reduce a distribution of a Vth of the SSL. The vertical memory device of FIG. 16 may additionally include the second dummy word line 170f′ between the SSL 170g and the word line 170f. Therefore, the increase of a resistance between the SSL and the word line which may occur due to an over-tail phenomenon of a second impurity region 138 may be effectively suppressed.

In example embodiments, the first dummy word line 170i, the SSLs 170g and 170h, the second dummy word line 170f′, and the word lines 170c through 170f may be arranged in the first direction by a substantially the same distance or pitch.

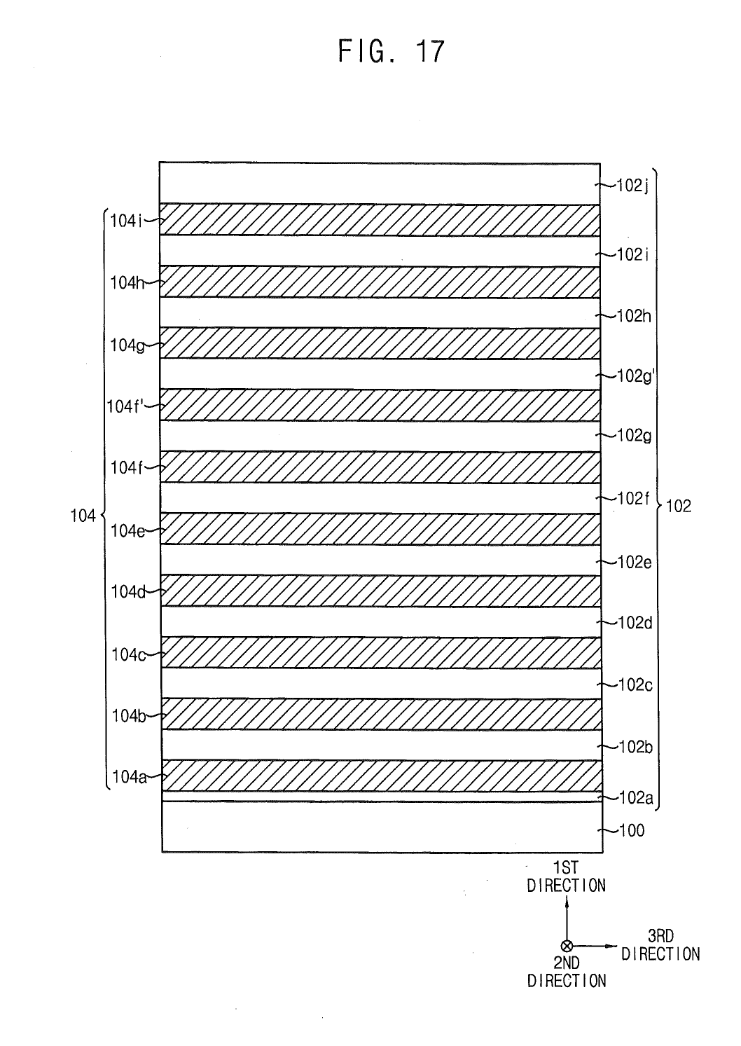

FIG. 17 is a cross-sectional view illustrating a method of manufacturing the vertical memory device of FIG. 16. Detailed descriptions on processes substantially the same as or similar to those illustrated with reference to FIGS. 2 to 15 are omitted.

Referring to FIG. 17, a process substantially the same as or similar to that illustrated with reference to FIG. 2 may be performed. Accordingly, insulating interlayers 102 and sacrificial layers 104 may be alternately and repeatedly formed on a substrate 100.

The sacrificial layers 104 may be removed by a subsequent process to provide spaces for forming gate electrodes 170. Thus, the number of the insulating interlayers 102 and the sacrificial layers 104 may be determined in consideration of the number of levels for forming the gate electrodes 170.

In example embodiments, the insulating interlayers 102 may be formed at 11 levels, and the sacrificial layers may be formed at 10 levels. Specifically, the insulating interlayer 102g′ and the sacrificial layer 104f′ may be added to the structure illustrated in FIG. 2.

Subsequently, processes substantially the same as or similar to those illustrated with reference to FIGS. 3 to 15 may be performed to obtain the vertical memory device of FIG. 16.

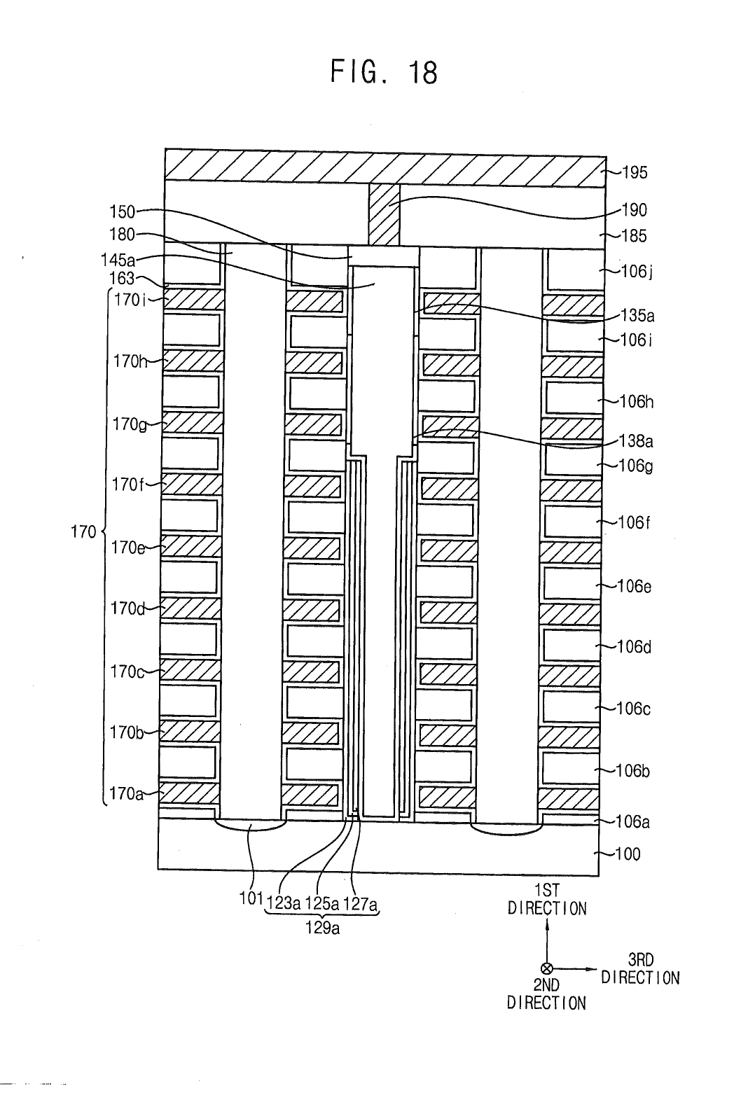

FIG. 18 is a cross-sectional view illustrating a vertical memory device in accordance with example embodiments. The vertical memory device may have a structure and/or a construction substantially the same as or similar to those illustrated with reference to FIGS. 1A and 1B except for a dielectric layer structure. Thus, detailed descriptions on elements substantially the same as or similar to those illustrated with reference to FIGS. 1A and 1B are omitted. Like reference numerals are used to indicate like elements.

Referring to FIG. 18, a dielectric layer structure 129a may be formed on a sidewall of a first opening 120 to surround an outer sidewall of a channel 135a. The dielectric layer structure 129a may include a tunnel insulation layer pattern 127a, a charge storage layer pattern 125a and a first blocking layer pattern 123a sequentially stacked from the outer sidewall of the channel 135a.

In example embodiments, the dielectric layer structure 129a may extend from a top surface of the substrate 100 to substantially cover GSLs 170a and 170b, and word lines 170c through 170f and not to cover SSLs 170g and 170h. For example, the dielectric layer structure 129a may have a top surface higher than a top surface of the uppermost word line 170f and lower than a bottom surface of the lower SSL 170g.

In this case, the channel 135a may be divided into an upper portion and a lower portion. The upper portion of the channel 135a may be adjacent to a first dummy word line 170i and the SSLs 170h and 170g. The lower portion of the channel 135a may be adjacent to the word lines 170c through 170f and the GSLs 170a and 170b.

The upper portion may be formed on the sidewall of the first opening 120 to contact a second blocking layer 163. The lower portion may contact the dielectric layer structure 129a. The upper portion may have a width or a diameter greater than that of the lower portion.

A second impurity region 138a may be formed at the upper portion of the channel 135a adjacent to the SSLs 170g and 170h.

In example embodiments, the upper portion of the channel 135a may not be in contact with the dielectric layer structure 129a having a multi-layered structure. The multi-layered structure may not be required to form transistors including the first dummy word line 170i or the SSLs 170g and 170h, and a single gate insulation layer may be sufficient for the transistors. Thus, the second blocking layer 163 may serve solely as a gate insulation layer with respect to the first dummy word line 170i and the SSLs 170g and 170h. The structure of the transistors may be simplified to have the single gate insulation layer so that an operation speed of the vertical memory device may be increased even with a lower voltage.

In one example embodiment, a second dummy word line (not illustrated) may be further disposed between the SSL 170g and the uppermost word line 170f. In this case, the upper portion of the channel 135a may extend to cover the first dummy word line 170i, the SSLs 170h and 170g, and the second dummy word line.

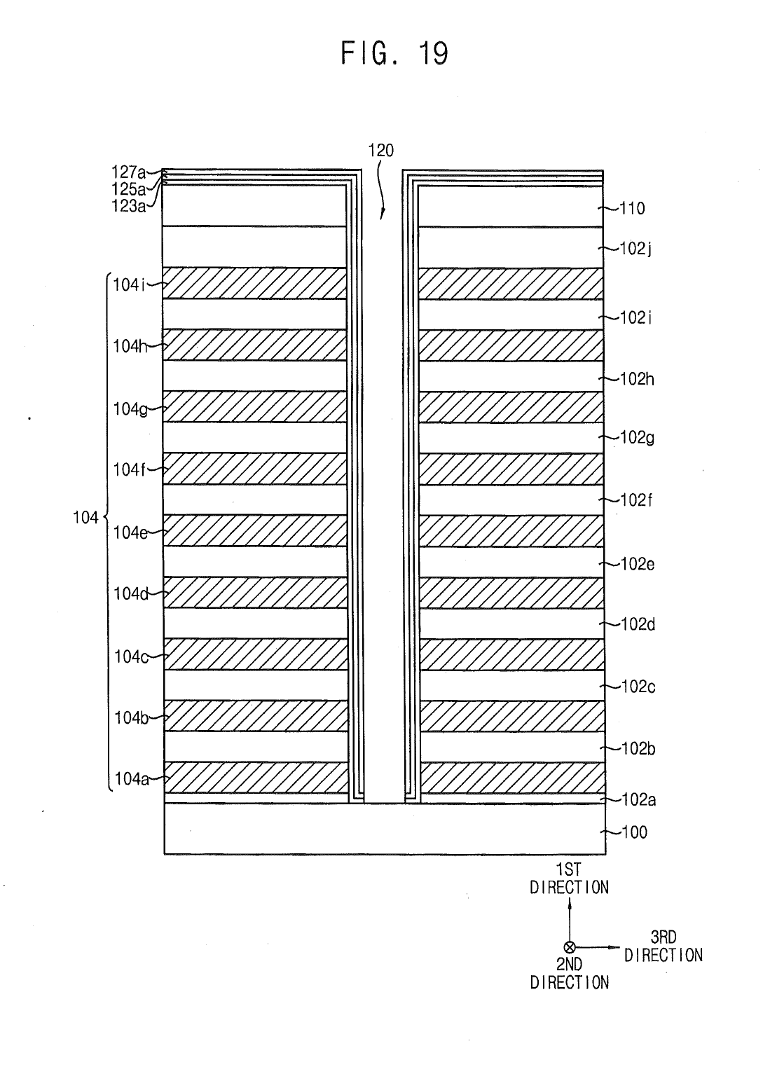

FIGS. 19 to 23 are cross-sectional views illustrating a method of manufacturing the vertical memory device of FIG. 18. Detailed descriptions on processes substantially the same as or similar to those illustrated with reference to FIGS. 2 to 15 are omitted.

Referring to FIG. 19, processes substantially the same as or similar to those illustrated with reference to FIGS. 2 to 5 may be performed.

Accordingly, insulating interlayers 102 and sacrificial layers 104 may be alternately and repeatedly formed on a substrate 100. The insulating interlayers 102 and the sacrificial layers 104 may be partially etched using a hard mask 110 that is formed on an uppermost insulating interlayer 102j to form a first opening 120. A first blocking layer pattern 123a, a charge storage layer pattern 125a and a tunnel insulation layer pattern 127a may be formed sequentially on the hard mask 110 and a sidewall of the first opening 120.

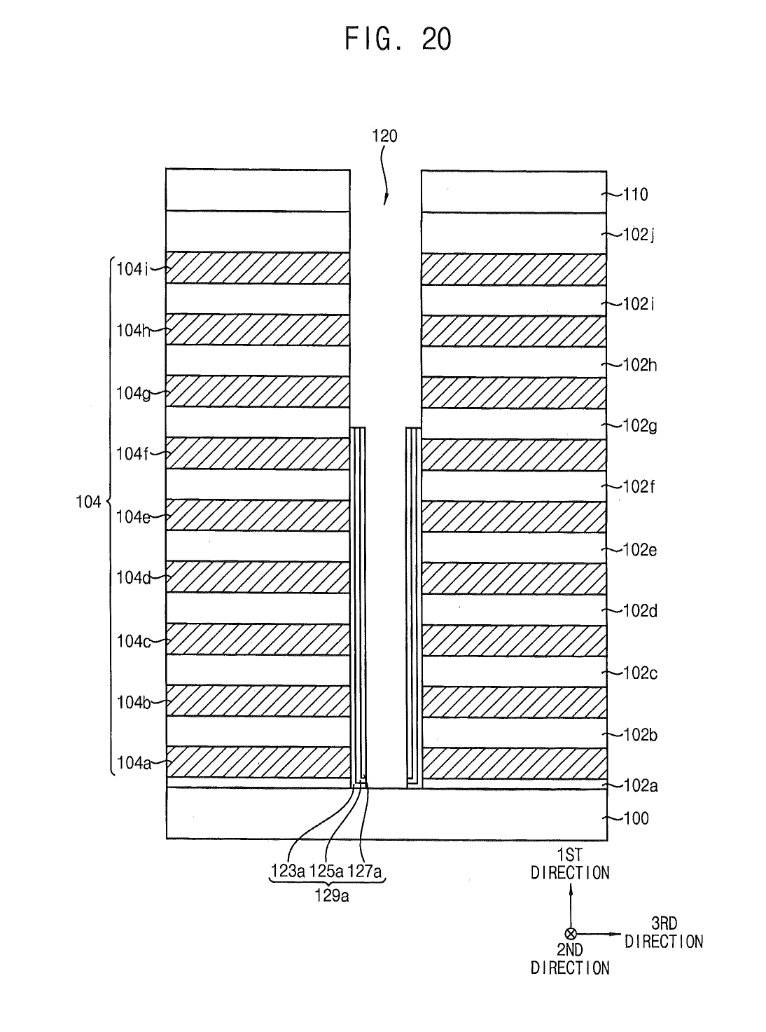

Referring to FIG. 20, upper portions of the first blocking layer pattern 123a, the charge storage layer pattern 125a and the tunnel insulation layer pattern 127a may be removed by, e.g., an etch-back process. Thus, a dielectric layer structure 129a extending from a top surface of the substrate 100 in the first direction and partially covering a sidewall of an insulating interlayer 102g may be obtained.

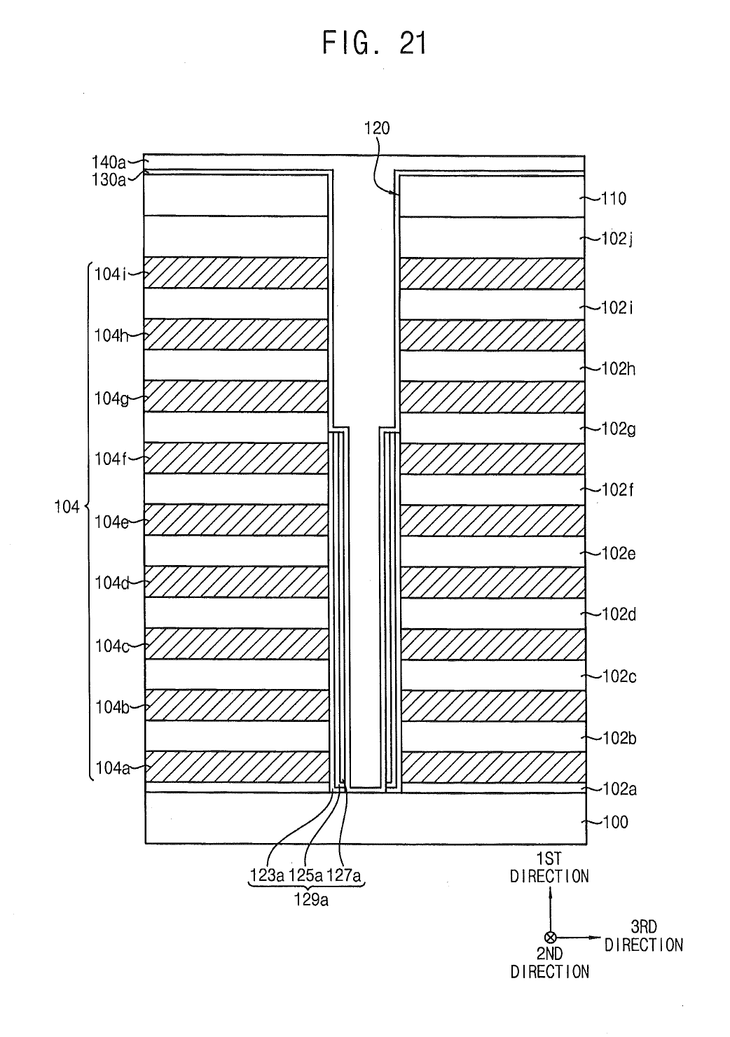

Referring to FIG. 21, a channel layer 130a may be formed conformally on the hard mask 110, the sidewall of the first opening 120, a surface of the dielectric layer structure 129a and the exposed top surface of the substrate 100. A first filling layer 140a may be formed on the channel layer 130a to sufficiently fill the first opening 120.

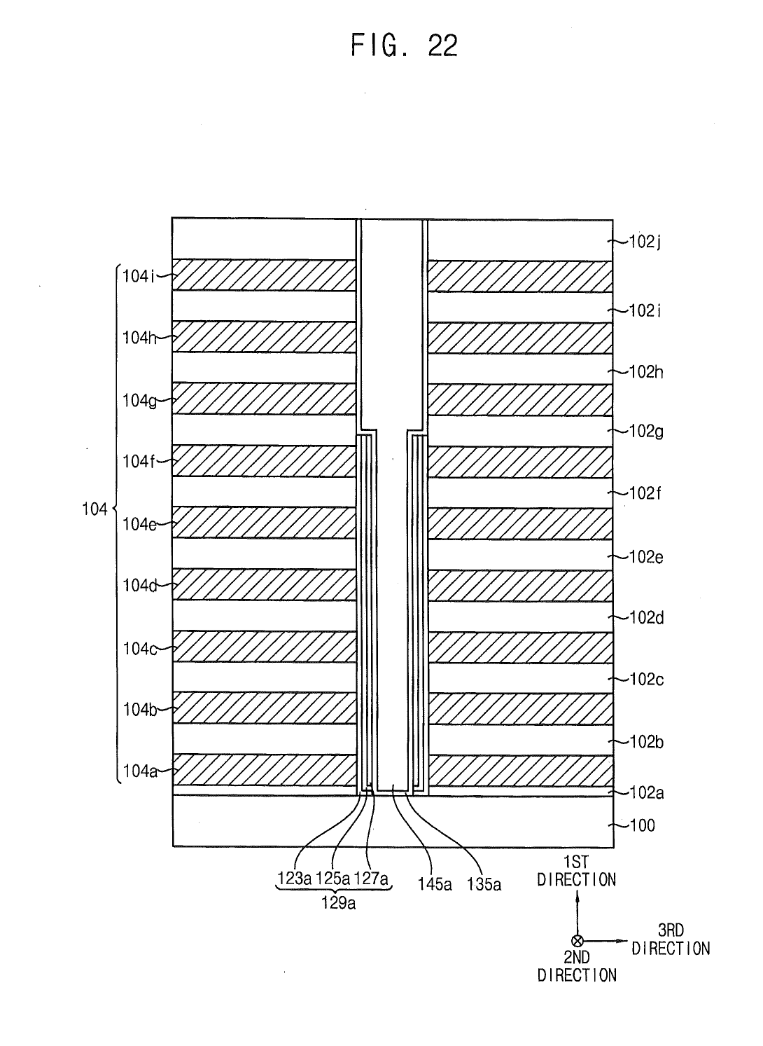

Referring to FIG. 22, the first filling layer 140a, the channel layer 130a and the hard mask 110 may be planarized until the uppermost insulating interlayer 102j is exposed to form a first filling layer pattern 145a and a channel 135a.

In example embodiments, the channel 135a may be divided into an upper portion and a lower portion. The upper portion of the channel 135a may be formed on the sidewall of the first opening 120 to be in contact with upper sacrificial layers 104g, 104h and 104i at 3 levels. The lower portion of the channel 135a may be in contact with the dielectric layer structure 129a. The upper portion of the channel 135a may have a width or a diameter greater than that of the lower portion of the channel 135a. In example embodiments, a boundary between the upper and lower portions may be defined at a portion adjacent to a sidewall of an insulating interlayer 102g.

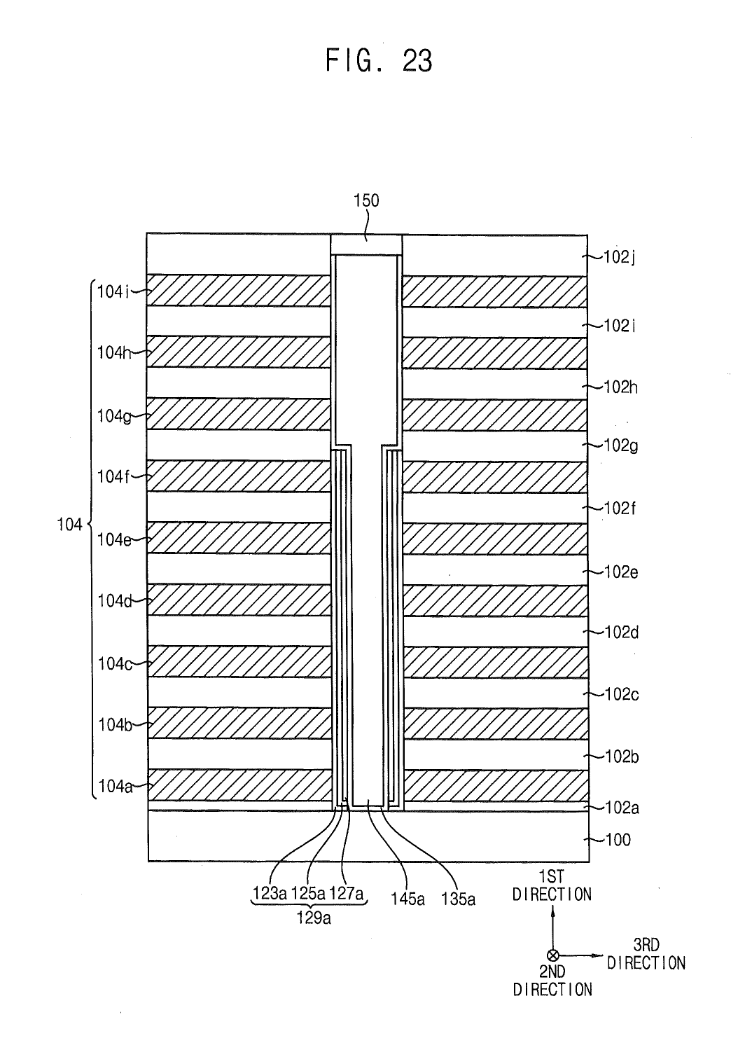

Referring to FIG. 23, a process substantially the same as or similar to that illustrated with reference to FIG. 8 may be performed to form a pad 150 on the channel 135a and the first filling layer pattern 145a.

Subsequently, processes substantially the same as or similar to those illustrated with reference to FIGS. 9 to 15 may be performed to obtain the vertical memory device of FIG. 18.

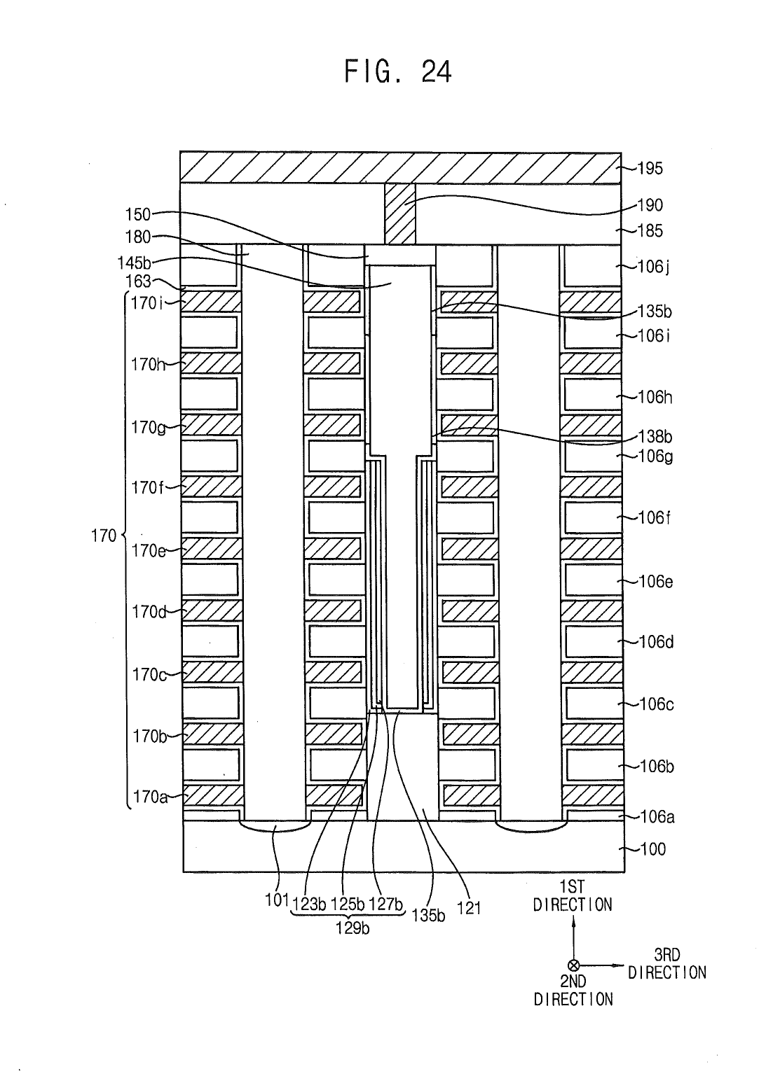

FIG. 24 is a cross-sectional view illustrating a vertical memory device in accordance with example embodiments. The vertical memory device may have a structure or a construction substantially the same as or similar to that illustrated with reference to FIG. 18 except for an addition of a semiconductor pattern. Thus, detailed descriptions on elements substantially the same as or similar to those illustrated with reference to FIG. 18 are omitted. Like reference numerals are used to indicate like elements.

Referring to FIG. 24, the vertical memory device may further include a semiconductor pattern 121 formed on a substrate 100 and filling a lower portion of a first opening 120.

A top surface of the semiconductor pattern 121 may be between a top surface of an upper GSL 170b and a bottom surface of a lowermost word line 170c. For example, the semiconductor pattern 121 may protrude from a top surface of the substrate 100 and may extend in the first direction to cover the GSLs 170a and 170b. The semiconductor pattern 121 may not cover the lowermost word line 170c.

The semiconductor pattern 121 may include a semiconductor material, e.g., polysilicon, single crystalline silicon, polygermanium or single crystalline germanium. In one example embodiment, the semiconductor pattern 121 may further include p-type impurities.

The semiconductor pattern 121 may serve as a channel of the GSLs 170a and 170b. A transistor involving the GSLs 170a and 170b may not include a dielectric layer structure 129b having a multi-layered structure due to a formation of the semiconductor pattern 121. In this case, a second blocking layer 163 may serve as a single gate insulation layer of the transistor. Thus, an operation speed and electrical characteristics of the vertical memory device may be improved.

The dielectric layer structure 129b may be formed on a peripheral portion of the top surface of the semiconductor pattern 121 and on a sidewall of the first opening 120. The dielectric layer structure 129b may include a first blocking layer structure 123b, a charge storage layer pattern 125b and a tunnel insulation layer pattern 127b sequentially stacked from the sidewall of the first opening 120.

In example embodiments, the dielectric layer structure 129b may extend in the first direction to cover word lines 170c, 170d, 170e and 170f, and not to cover SSLs 170g and 170h. For example, a top surface of the dielectric layer structure 129b may be between a top surface of the uppermost word line 170f and a bottom surface of the lower SSL 170g.

A channel 135b may be formed conformally on the top surface of the semiconductor pattern 121, a surface of the dielectric layer structure 129b and the sidewall of the first opening 120.

In example embodiments, the channel 135b may be divided into an upper portion and a lower portion. The upper portion of the channel 135b may be adjacent to a dummy word line 170i and the SSLs 170h and 170g. The lower portion of the channel 135b may be adjacent to the word lines 170f, 170e, 170d and 170c.

The upper portion of the channel 135b may be formed on the sidewall of the first opening 120 to be in contact with the second blocking layer 163. The lower portion of the channel 135b may be in contact with the dielectric layer structure 129b and the semiconductor pattern 121. The upper portion may have a width or a diameter greater than that of the lower portion.

A second impurity region 138b may be formed at a portion of the channel 135b adjacent to the SSLs 170g and 170h.

In one example embodiment, a second dummy word line (not illustrated) may be further disposed between the SSL 170g and the uppermost word line 170f as illustrated in FIG. 16. In this case, the upper portion of the channel 135b may extend to cover the first dummy word line 170i, the SSLs 170g and 170h, and the second dummy word line.

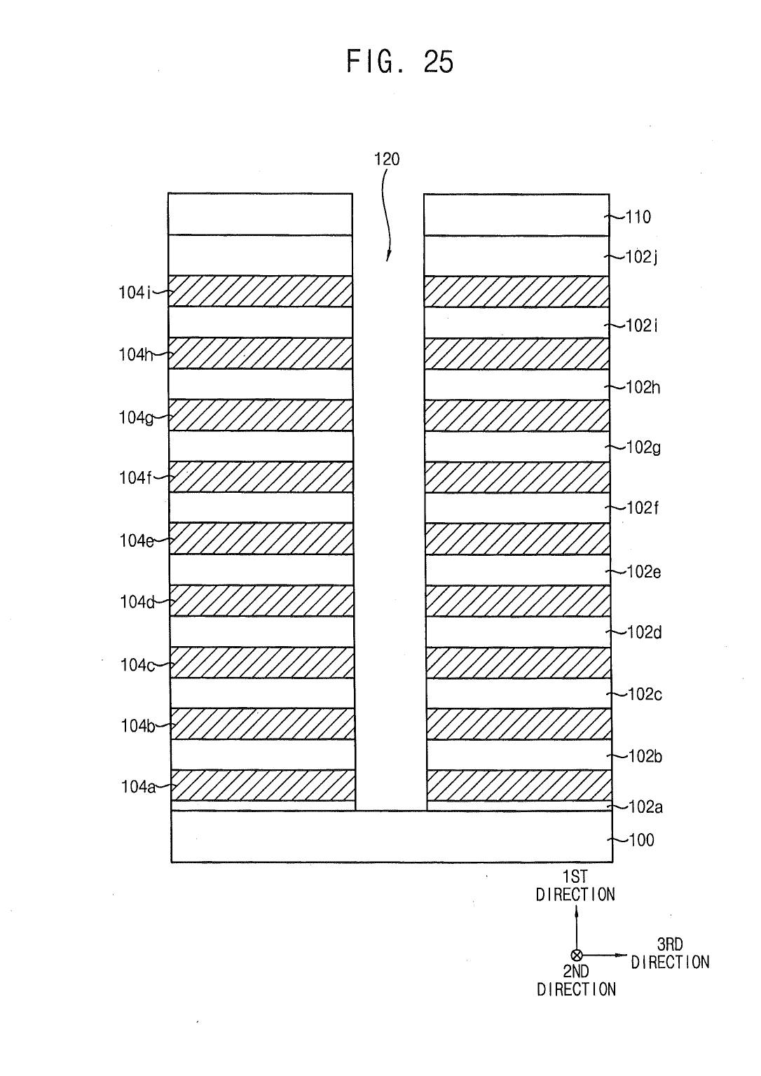

FIGS. 25 to 30 are cross-sectional views illustrating a method of manufacturing the vertical memory device of FIG. 24. Detailed descriptions on processes substantially the same as or similar to those illustrated with reference to FIGS. 2 to 15 and FIGS. 19 to 23 are omitted.

Referring to FIG. 25, processes substantially the same as or similar to those illustrated with reference to FIGS. 2 and 3 may be performed. Accordingly, a first opening 120 may be formed through insulating interlayers 102 and sacrificial layers 104 alternately and repeatedly formed on a substrate 100.

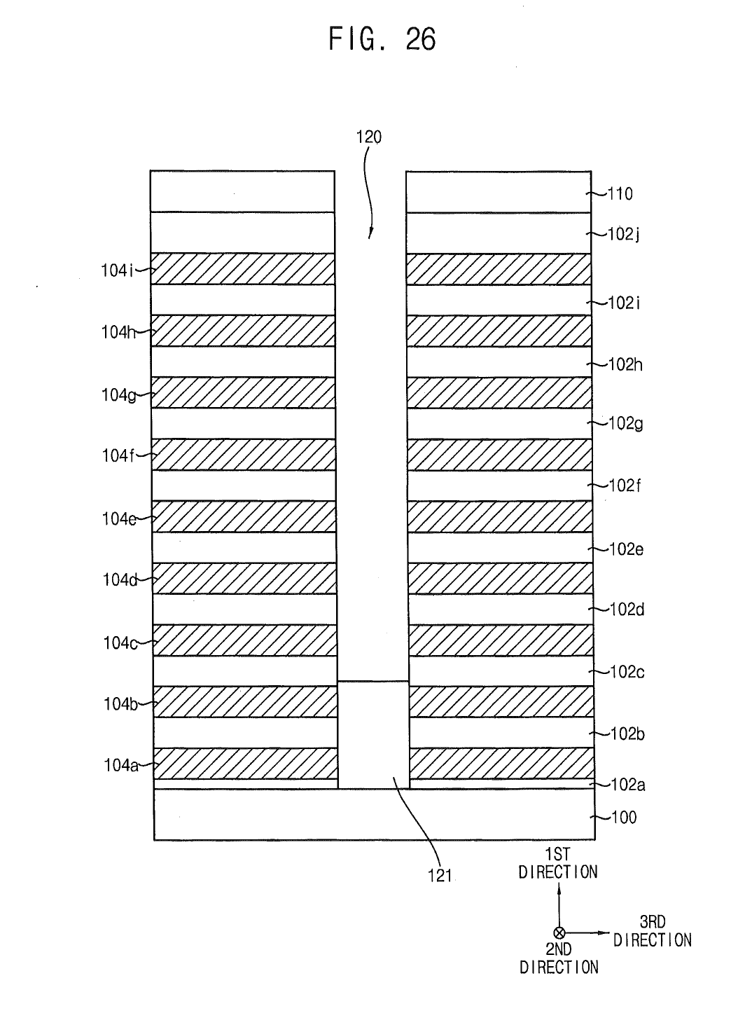

Referring to FIG. 26, a semiconductor pattern 121 may be formed on the substrate 100 to partially fill the first opening 120.

In example embodiments, the semiconductor pattern 121 may be formed by a selective epitaxial growth (SEG) using a top surface of the substrate 100 as a seed. Accordingly, the semiconductor pattern 121 may be formed to include single crystalline silicon or single crystalline germanium. In one example embodiment, an amorphous silicon layer filling the first opening 120 may be formed, and then a laser epitaxial growth (LEG) process or a solid phase epitaxi (SPE) process may be performed to obtain the semiconductor pattern 121. In one example embodiment, the semiconductor pattern 121 may include, e.g., p-type impurities.

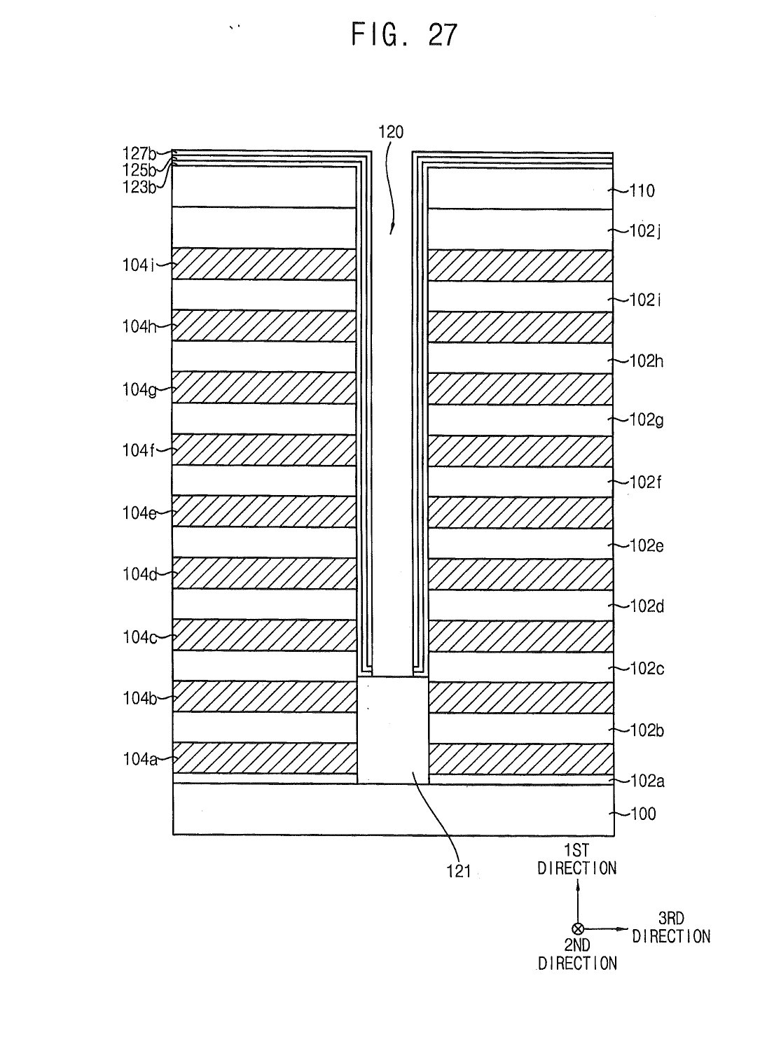

Referring to FIG. 27, processes substantially the same as or similar to those illustrated with reference to FIGS. 4 and 5 may be performed. Accordingly, a first blocking layer pattern 123b, a charge storage layer pattern 125b and a tunnel insulation layer pattern 127b may be sequentially formed on a hard mask 110, a sidewall of the first opening 120 and a portion of the semiconductor pattern 121.

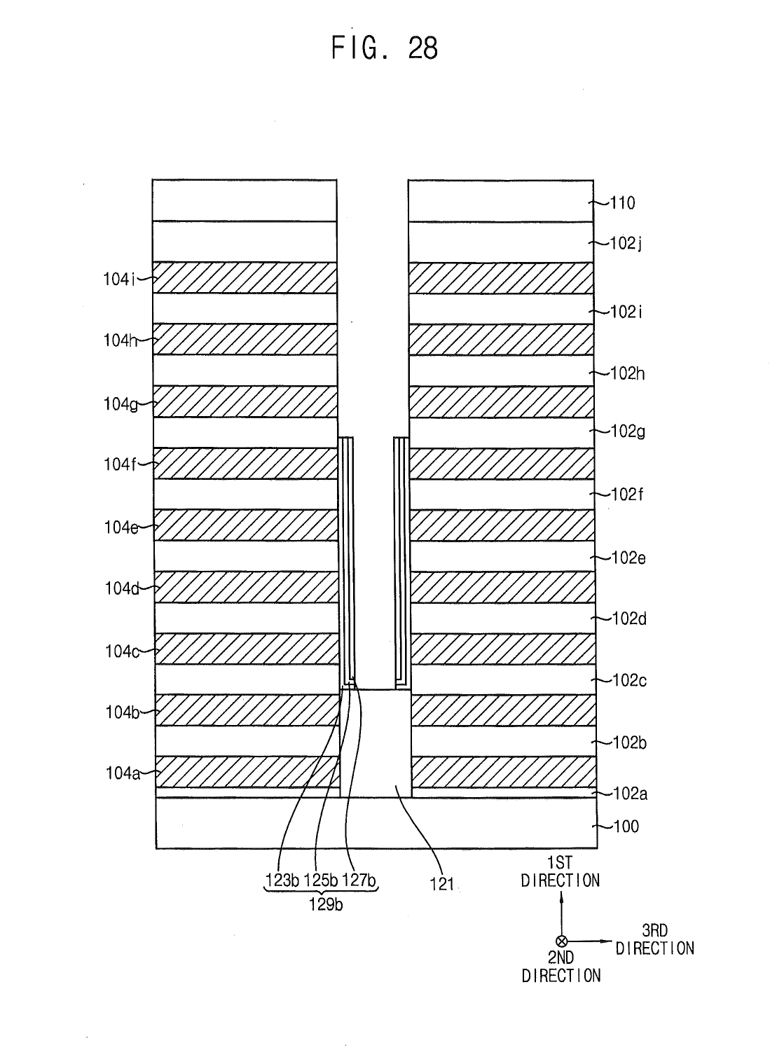

Referring to FIG. 28, a process substantially the same as or similar to that illustrated with reference to FIG. 20 may be performed. Accordingly, a dielectric layer structure 129b including the first blocking layer pattern 123b, the charge storage layer pattern 125b and the tunnel insulation layer pattern 127b may be formed. The dielectric layer structure 129b may extend from a top surface of the semiconductor pattern 121 to cover a sacrificial layer 104f and a portion of an insulating interlayer 102g on the sacrificial layer 104f. In example embodiments, the sacrificial layer 104f may be replaced with an uppermost word line.

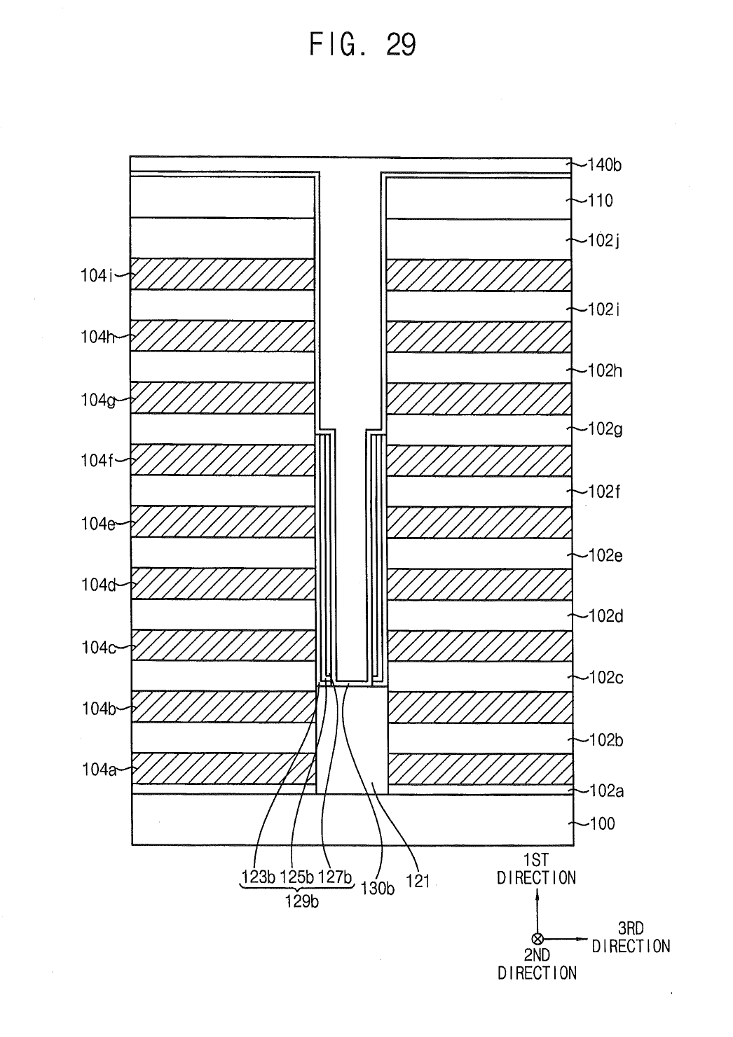

Referring to FIG. 29, a process substantially the same as or similar to that illustrated with reference to FIG. 21 may be performed. Accordingly, a channel layer 130b may be formed conformally on the hard mask 110, the sidewall of the first opening 120, the dielectric layer structure 129b and the semiconductor pattern 121. A first filling layer 140b may be formed on the channel layer 130b to fill a remaining portion of the first opening 120.

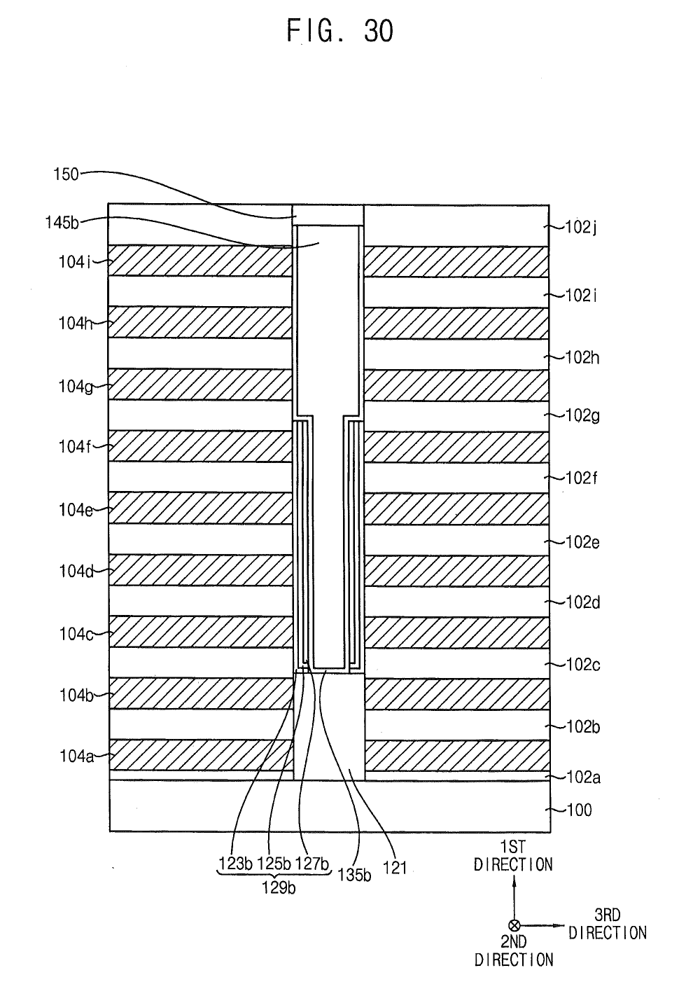

Referring to FIG. 30, processes substantially the same as or similar to those illustrated with reference to FIGS. 22 and 23 may be performed to form a channel 135b, a first filling layer pattern 145b and a pad 150.

In example embodiments, the channel 135b may be divided into an upper portion and a lower portion. The upper portion of the channel 135b may be formed on the sidewall of the first opening 120 to be in contact with upper sacrificial layers 104g, 104h and 104i at 3 levels. The lower portion of the channel 135b may be in contact with the dielectric layer structure 129b and the semiconductor pattern 121. The upper portion of the channel 135b may have a width or a diameter greater than that of the lower portion of the channel 135b. In example embodiments, a boundary between the upper and lower portions may be defined at a portion adjacent to a sidewall of the insulating interlayer 102g.

Subsequently, processes substantially the same as or similar to those illustrated with reference to FIGS. 9 to 15 may be performed to obtain the vertical memory device illustrated in FIG. 24.

The vertical memory device according to example embodiments may be employed to various systems, e.g., an information processing system.

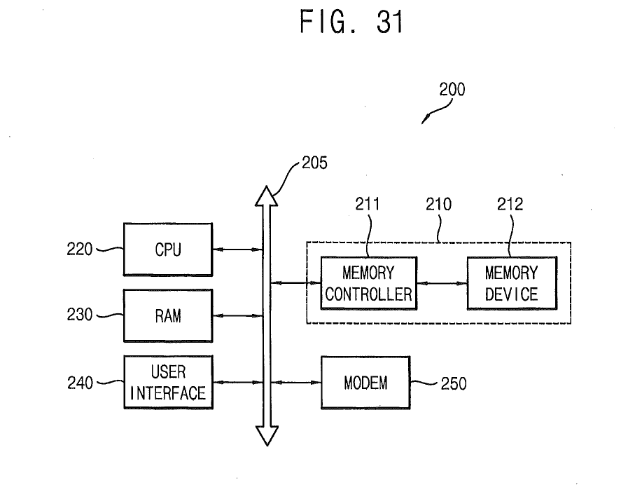

FIG. 31 is a block diagram illustrating a schematic construction of an information processing system in accordance with example embodiments.

Referring to FIG. 31, an information processing system 200 may include a CPU 220, a RAM 230, a user interface 24Q, a modem 250 such as a baseband chipset and a memory system 210 electrically connected to a system bus 205. The memory system 210 may include a memory device 212 and a memory controller 211. The memory device 212 may include the vertical memory device according to example embodiments. Thus, large data processed by the CPU 220 or input from an external device may be stored in the memory device 212 with high stability. The memory controller 211 may have a construction capable of controlling the memory device 212. The memory system 210 may be provided as, e.g., a memory card or a solid state disk (SSD) by a combination of the memory device 212 and the memory controller 211. In a case that the information processing system 200 is utilized for a mobile device, a battery may be further provided for supplying an operation voltage of the information processing system 200. The information processing system 200 may further include an application chipset, a camera image processor (CIS), a mobile DRAM, etc.

According to example embodiments, a vertical memory device may include a dummy word line on a SSL or between the SSL and a word line. A predetermined turn-on voltage may be provided to the dummy word line so that an increase of an electrical resistance caused by a formation of an impurity region at a channel adjacent to the SSL may be prevented. Additionally, an increase of a distribution of a Vth caused by an over-tail phenomenon of the impurity region may be suppressed by the dummy word line.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A vertical memory device, comprising:
a channel extending in a vertical direction with respect to a top surface of a substrate; and
gate electrodes disposed on an outer sidewall of the channel, the gate electrodes including a ground selection line (GSL), a word line, a string selection line (SSL) and a first dummy word line sequentially stacked from the top surface of the substrate in the vertical direction to be spaced apart from each other,
wherein the channel includes an impurity region at a portion adjacent to the SSL.

2. The vertical memory device of claim 1, wherein the gate electrodes further includes a second dummy word line between the word line and the SSL.

3. The vertical memory device of claim 2, wherein the SSL, the second dummy word line and the word line are arranged in the vertical direction by the same distance.

4. The vertical memory device of claim 1, further comprising a dielectric layer structure between the channel and the gate electrodes, the dielectric layer structure extending from the top surface of the substrate in the vertical direction.

5. The vertical memory device of claim 4, wherein a top surface of the dielectric layer structure is located between a bottom surface of the SSL and a top surface of the word line.

6. The vertical memory device of claim 5, wherein the dielectric layer structure includes a tunnel insulation layer pattern, a charge storage layer pattern and a blocking layer pattern sequentially stacked from the outer sidewall of the channel.

7. The vertical memory device of claim 6, wherein a single gate insulation layer is disposed on a portion of the outer sidewall of the channel which is not covered by the dielectric layer structure.

8. The vertical memory device of claim 4, further comprising a second dummy word line between the word line and the SSL,
wherein a top surface of the dielectric layer structure is located between a bottom surface of the second dummy word line and a top surface of the word line.

9. The vertical memory device of claim 4, wherein the channel includes a semiconductor pattern disposed on the top surface of the substrate,
wherein a top surface of the semiconductor pattern is located between a top surface of the GSL and a bottom surface of the word line.

10. The vertical memory device of claim 9, wherein the dielectric layer structure extends from the top surface of the semiconductor substrate.

11. The vertical memory device of claim 1, wherein the first dummy word line is configured to receive a predetermined turn-on voltage.

12. The vertical memory device of claim 11, wherein the predetermined turn-on voltage has a value between a threshold voltage of the SSL and a read voltage of the word line.

13. A vertical memory device, comprising:
a plurality of gate electrodes and insulating layers alternately stacked in a vertical direction from a top surface of a substrate; and
a channel extending from the top surface of the substrate in a vertical direction through the gate electrodes and insulating layers, wherein an upper sidewall region of the channel laterally adjacent to an upper one of the gate electrodes has a different impurity concentration than a lower sidewall region of the channel laterally adjacent to a lower one of the gate electrodes below the upper one of the gate electrodes.

14. The vertical memory device of claim 13, wherein an upper boundary of the lower sidewall region is laterally adjacent to one of the insulating layers between the upper one of the gate electrodes and the lower one of the gate electrodes.

15. The vertical memory device of claim 14, wherein the upper one of the gate electrodes is configured to receive a predetermined turn-on voltage having a value different than a value of a threshold voltage of the lower one of the gate electrodes.

16. The vertical memory device of claim 15, wherein the upper one of the gate electrodes comprises a dummy word line and the lower one of the gate electrodes comprises a string selection line (SSL).

17. The vertical memory device of claim 16, wherein the dummy word line is a first dummy word line, wherein the plurality of gate electrodes further comprises a word line below the SSL and a ground select line (GSL) below the word line, and wherein the plurality of gate electrodes further comprises a second dummy word line between the SSL and the word line.

18. The vertical memory device of claim 17, wherein the second dummy word line is configured to receive the predetermined turn-on voltage.

19. The vertical memory device of claim 18, wherein a lower boundary of the lower sidewall region is laterally adjacent to an insulating layer between the SSL and the second dummy word line.

20. The vertical memory device of claim 13, wherein the lower sidewall region of the channel has a greater impurity concentration than the upper sidewall region of the channel.
